(19) United States
(12) Patent Application Publication
(10) Pub. No.: US 2013/0153861 A1
(43) Pub. Date: Jun. 20, 2013

(54) ORGANIC OPTOELECTRONIC DEVICES WITH SURFACE PLASMON STRUCTURES AND METHODS OF MANUFACTURE

(71) Applicants: Bozena KAMINSKA, Vancouver (CA); Badr OMRANE, Vancouver (CA); Clinton K. LANDROCK, North Vancouver (CA)

(72) Inventors: Bozena KAMINSKA, Vancouver (CA); Badr OMRANE, Vancouver (CA); Clinton K. LANDROCK, North Vancouver (CA)

(21) Appl. No.: 13/329,075

(22) Filed: Dec. 16, 2011

(51) Int. Cl. H01L 51/50; H01L 31/18; H01L 51/40; B82Y 30/00

(52) U.S. Cl. 257/40; 438/22; 438/82; 257/E51.018; 257/E51.024; 257/E31.001; 977/932

(57) ABSTRACT

An organic optoelectronic device is disclosed. The organic optoelectronic device includes a carrier substrate, an anode electrode layer disposed at least partially on the carrier substrate, an organic electronic active region including one or more organic layers and disposed at least partially on the anode electrode layer, and a cathode electrode layer disposed at least partially on the organic photoactive layer. The anode electrode layer has a periodic array of sub-wavelength nanostructures. Methods of manufacturing an organic optoelectronic device are also disclosed.

### 1. TECHNICAL FIELD

The present invention relates generally to organic optoelectronic devices, and more particularly, to organic optoelectronic devices with surface plasmonic structures to enhance their performance and/or their methods of manufacture.

### 2. Background of the Invention

Research in bulk heterojunction (“BHJ”) structures has led to the development of organic photovoltaics devices (“OPVs”) with efficiency close to 9%. Nevertheless, a reliance on indium tin oxide (“ITO”) remains a key limiting factor in the design and performance of OPVs and other organic optoelectronic devices (“OODs”).

ITO as a transparent conductor is known to have several disadvantages and design and performance constraints. First, ITO as used in an OOD is a major cause of device degradation. ITO has a tendency to crack or break when deposited on flexible substrates and subjected to bending. The formation and propagation of cracks in the ITO in turn increase its electrical resistance, resulting in a loss of conductivity. ITO tends to degrade over time, permitting oxygen and moisture to diffuse into the organic layers of the OOD and adversely affecting the DOD's operational lifetime. A further disadvantage of ITO is cost. ITO requires indium, which due to scarcity has high material cost that prevents the wide deployment of ITO in cost-conscious industries, such as in the OPV industry. ITO also suffers from the compromise between conductivity and transparency. During ITO film deposition, the high concentration of charge carriers increases the conductivity of the ITO, but decreases its transparency, which is undesirable, as OODs typically require both high anode conductivity and transparency to deliver optimal device performance.

Although transparent films of carbon nanotubes or highly conductive polymers have been proposed as replacements to ITO, the performance of OPVs and other OODs have not been substantially enhanced to date as a result.

A need, therefore, exists for an alternative optically transmissive conductor suitable for application in OODs without the disadvantages associated with ITO materials.

### 3. SUMMARY OF THE INVENTION

In accordance with a first aspect, an organic optoelectronic device is disclosed. The organic optoelectronic device includes a carrier substrate, a metal anode electrode layer disposed at least partially on the carrier substrate, an organic electronic active region including one or more organic layers and disposed at least partially on the metal anode electrode layer, and a cathode electrode layer disposed at least partially on the organic photoactive layer. The metal anode electrode layer includes periodic arrays of sub-wavelength nanostructures.

In accordance with an additional aspect, a method of manufacturing an organic optoelectronic device is also disclosed. The method of manufacturing an organic optoelectronic device includes forming a metal anode electrode layer at least partially on a carrier substrate; forming a periodic array of sub-wavelength nanostructures in the metal anode electrode layer defined as the perforated metal anode electrode layer; forming an organic electronic active region at least partially on the perforated metal anode electrode layer, the organic electronic active region comprising one or more organic layers; and forming a cathode electrode layer at least partially on the organic electronic active region.

In accordance with a further aspect, a method of manufacturing an organic photovoltaic device is disclosed. The method of manufacturing an organic photovoltaic device includes the steps of: determining a peak optical absorption wavelength of an organic photoactive layer to be formed at least partially on a metal anode electrode layer; defining a desired peak optical transmission wavelength of a periodic array of sub-wavelength nanostructures adapted to be formed in the metal anode electrode layer based on said determined peak optical absorption wavelength of said organic photoactive layer; determining a desired periodicity of said periodic array of sub-wavelength nanostructures based at least in part on said desired peak optical transmission wavelength of said periodic array of sub-wavelength nanostructures, a dielectric constant of said carrier substrate, and a dielectric constant of said metal anode electrode layer; defining a desired optical transmission bandwidth of said periodic array of sub-wavelength nanostructures based on an optical absorption bandwidth of said organic photoactive layer; and defining a desired geometry of each of said nanostructures and a desired thickness of said metal anode electrode layer based on said desired optical transmission bandwidth of said periodic array of sub-wavelength nanostructures

Following the preceding steps, the method of manufacturing an organic photovoltaic device proceeds to forming said metal anode electrode layer with said desired thickness at least partially on a carrier substrate; forming said periodic array of sub-wavelength nanostructures in said metal anode electrode layer with said desired geometry for each of said nanostructures and with said desired periodicity; forming organic layers with at least one being photoactive at least partially on said metal anode electrode layer; and forming a cathode electrode layer at least partially on said organic photoactive layer.

In accordance with a yet further aspect, a method of manufacturing an organic light emitting diode device is disclosed. The method of manufacturing an organic light emitting diode device includes the steps of: determining a peak optical emission wavelength of an organic emissive electroluminescent layer to be formed at least partially on a metal anode electrode layer; defining a desired peak optical transmission wavelength of a periodic array of sub-wavelength nanostructures adapted to be formed in the metal anode electrode layer based on said determined peak optical emission wavelength of said organic emissive electroluminescent layer; determining a desired periodicity of said periodic array of sub-wavelength nanostructures based at least in part on said desired peak optical transmission wavelength of said periodic array of sub-wavelength nanostructures, a dielectric constant of said organic photoactive layer, and a dielectric constant of said metal anode electrode layer; defining a desired optical transmission bandwidth of said periodic array of sub-wavelength nanostructures based on an optical transmission bandwidth of said organic emissive electroluminescent layer; and defining a desired geometry of each of said nanostructures and a desired thickness of said metal anode electrode layer based on said desired optical transmission bandwidth of said periodic array of sub-wavelength nanostructures.

Following the preceding steps, the method of manufacturing a light emitting diode device proceeds to forming said metal anode electrode layer with said desired thickness at least partially on a carrier substrate; forming said periodic array of sub-wavelength nanostructures in said metal anode electrode layer with said desired geometry for each of said nanostructures and with said desired periodicity; forming organic layers with at least one being an emissive electroluminescent layer at least partially on said metal anode electrode layer; and forming a cathode electrode layer at least partially on said organic emissive electroluminescent layer.

In accordance with another embodiment of the present invention, an organic optoelectronic device is provided, comprising: a carrier substrate; a cathode electrode layer disposed at least partially on the carrier substrate, the cathode electrode layer having a periodic array of sub-wavelength nanostructures; an organic electronic active region disposed at least partially on the cathode electrode layer, the organic electronic active region comprising one or more organic layers; and an anode electrode layer disposed at least partially on the organic photoactive layer.

Further advantages of the invention will become apparent when considering the drawings in conjunction with the detailed description.

### 4. BRIEF DESCRIPTION OF THE DRAWINGS

The organic optoelectronic device and the method of manufacturing an OOD of the present invention will now be described with reference to the accompanying drawing figures, in which:

FIG. 1 illustrates a cross-sectional view of an OOD according to an exemplary embodiment of the invention.

FIG. 2 illustrates a cross-sectional view of an OOD having the construction of an OPV according to an embodiment of the invention.

FIG. 3 illustrates a cross-sectional view of an OOD having the construction of an OLED according to an embodiment of the invention.

FIG. 4 illustrates a perspective view of the metal anode electrode layer of the OOD, the OPV, and the OLED shown in respective FIGS. 1-3.

FIG. 5 illustrates a flow diagram of a method of manufacturing an OOD according to an exemplary embodiment of the invention.

FIG. 6 illustrates a flow diagram of a method for defining the geometrical parameters of the periodic array and the nanoholes adapted for the manufacturing of the OPV according to an exemplary embodiment of the invention.

FIG. 7 illustrates a flow diagram of a method for defining the geometrical parameters of the periodic array and the nanoholes adapted for the manufacturing of the OLED according to another exemplary embodiment of the invention.

FIG. 8 illustrates a plot of several transmission curves (i.e. intensity versus wavelength) for a plurality of silver metal anode layers perforated with periodic nanohole arrays of 400 nm-600 nm in periodicity according to an embodiment of the invention.

FIG. 9 illustrates a plot of a transmission curve of a nanohole-perforated silver metal anode layer with a periodicity of 450 nm according to an embodiment of the invention, and a transmission curve of an ITO layer on a glass substrate.

FIG. 10 illustrates a plan schematic view of a periodic array of nanoholes arranged to form a hexagonal lattice sub-wavelength nanostructure according to an embodiment of the invention.

FIG. 11 illustrates a scanning electron microscope (SEM) image of a hexagonal lattice sub-wavelength nanostructure as shown in FIG. 10, according to an embodiment of the invention.

FIG. 12A illustrates a plan schematic view of a periodic pattern of nanoholes arranged to form a concentric circular sub-wavelength nanostructure according to an embodiment of the invention.

FIG. 12B illustrates an SEM image of a concentric circular sub-wavelength nanostructure as shown in FIG. 12A comprising substantially annular openings, according to one embodiment of the invention.

FIG. 13 illustrates an SEM image of a concentric circular sub-wavelength nanostructure as shown in FIG. 12A comprising nanoholes arranged in a plurality of rings about a central nanohole, according to another embodiment of the invention.

FIG. 14A illustrates a plan schematic view of a periodic pattern of nanoholes arranged to form an annular ring sub-wavelength nanostructure according to an embodiment of the invention.

FIG. 14B illustrates an SEM image of a periodic pattern of annular ring sub-wavelength nanostructures as shown in FIG. 14A, according to a further embodiment of the invention.

FIG. 15A illustrates a plan schematic view of a periodic pattern of multiple concentric rings of nanoholes arranged to form a hexagonal lattice sub-wavelength nanostructure, according to an embodiment of the invention.

FIG. 15B illustrates an SEM image of a periodic pattern of multiple concentric rings of nanoholes arranged in a hexagonal lattice sub-wavelength nanostructure as shown in FIG. 15A, according to another embodiment of the invention.

FIG. 16A illustrates a plan schematic view of a periodic pattern of concentric nanohole rings around central nanoholes to form sub-wavelength nanostructures, according to an embodiment of the invention.

FIG. 16B illustrates an SEM image of a periodic pattern of concentric nanohole rings around central nanoholes arranged in a sub-wavelength nanostructure as shown in FIG. 16A, according to a further embodiment of the invention.

FIG. 17 illustrates a spectrogram plot of transmitted light bandwidths and intensities for several sub-wavelength nanostructures with exemplary periodic patterns such as those shown in FIGS. 10-16, according to an embodiment of the invention.

Further advantages of the invention will become apparent when considering the drawings in conjunction with the detailed description.

Similar reference numerals refer to corresponding parts throughout the several views of the drawings.

### 5. DETAILED DESCRIPTION OF THE INVENTION

In one embodiment of the present invention, an ordered or periodic array of sub-wavelength nanostructures is optimally formed in a metal layer, such as an exemplary metallic foil or film, for use as an anode in an organic optoelectronic device (“OOD”), such as in an organic photovoltaic device (“OPV”) or an organic light emitting diode device (“OLED”), for example. The metal anode layer comprising one or more nanostructures may be desirably adapted for use in an OOD as a replacement or alternative to a conventional high work function, optically-transmissive front electrode, which is typically made of indium tin oxide (“ITO”). As compared to conventional ITO-OODs, the ITO-free OOD configuration of the present invention leverages the relatively higher conductivity of metal as the anode materials (e.g. silver (Ag), gold (Au), and copper (Cu)), and the Surface Plasmonic (“SP”) and Extraordinary Optical Transmission (“EOT”) properties observed in the perforated metal anode electrode layer to desirably increase OOD device efficiency.

EOT is a strong enhancement of optical transmission observed when a metal film is perforated with an array of holes having sub-wavelength-geometries. The phenomenon of EOT has been identified as the result of the interaction of Surface Plasmons (“SPs”) with photons. SPs are typically understood to be the oscillations of free electrons at the interface of a metal and a dielectric. Photons incident at the interface between the metal and dielectric layers interact resonantly with and cause excitation of the SPs, whereby the SPs couple with the photons to form surface plasmon polaritons (“SPP”). It has been shown that SPPs cause incident light to transmit through a metal film perforated with an array of sub-wavelength holes and a strong enhancement of optical transmission is observed for a specified wavelength range of the light transmitted through the sub-wavelength holes in the metal film material.

One embodiment of the invention applies the principles of SP and EOT in an OOD to configure the optical transmission properties of a fully or partially perforated metal anode electrode layer such that the maximum amount of useful photons are exploited to effect the operation of the OOD, as will be discussed later in detail. As compared to a conventional ITO-based OOD, the end result of such an embodiment of the invention is effectively an OOD comprised of a metal anode layer with nanostructures that advantageously resists against OOD device degradation, and provides higher anode conductivity, lower manufacturing costs, and fewer manufacturing steps. Certain embodiments of the OOD of the invention adapted for OPV applications also exhibit significantly higher power conversion efficiencies compared to conventional ITO-OPVs.

### Organic Optoelectronic Device 100

The present invention will now be further described with reference to the Figures.

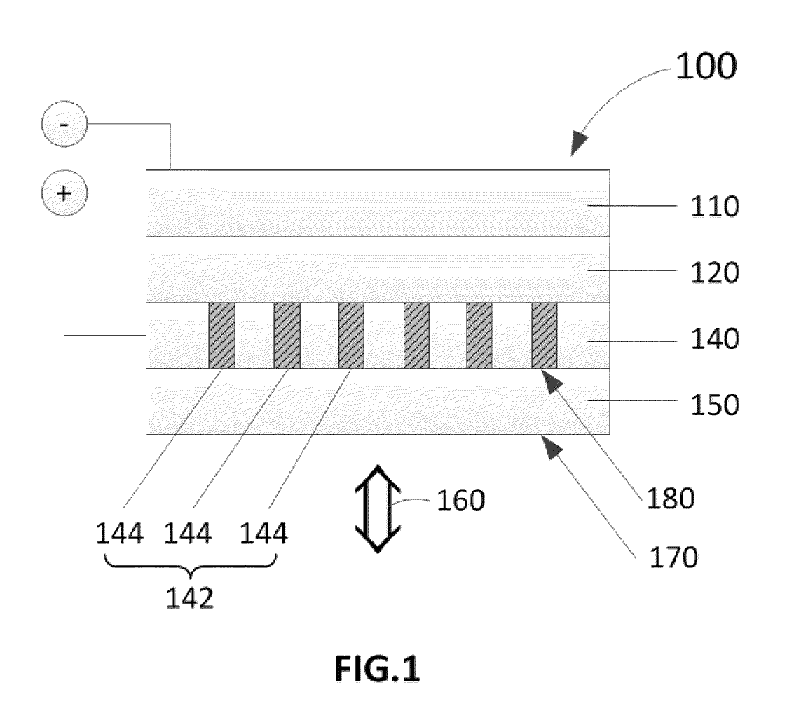

FIG. 1 is a cross-sectional view of an OOD 100 according to an exemplary embodiment of the invention. The OOD 100 includes a carrier substrate 150 and a metal anode electrode layer 140 disposed at least partially on the carrier substrate 150. The metal anode electrode layer 140 has an ordered or periodic array 142 of sub-wavelength nanostructures (e.g. nanoholes 144) perforated therethrough. The OOD 100 further includes an organic electronic active region 120 disposed at least partially on the metal anode electrode layer 140 and a cathode electrode layer 110 disposed at least partially on the organic electronic active region 120.

As used herein, a “layer” of a given material includes a region of that material the thickness of which is smaller than either of its length or width. Examples of layers may include sheets, foils, films, laminations, coatings, blends of organic polymers, metal plating, and adhesion layer(s), for example. Further, a “layer” as used herein need not be planar, but may alternatively be folded, bent or otherwise contoured in at least one direction, for example.

Still referring to FIG. 1, the materials for constructing the carrier substrate 150 and the exemplary anode electrode layer 140 of the OOD 100 (e.g. OPV 101 and OLED 102) are advantageously selected such that surface plasmons (SP) (not shown) exist at the interface 180 therebetween. Preferably, materials for the carrier substrate 150 are further substantially optically transparent and capable of supporting the organic layer(s) of the organic electronic active region 120, and the electrode layers 110 and 140 disposed thereon. Exemplary such materials include plastic and glass, for example, but other suitable known dielectric materials may be also be used. Suitable exemplary materials for the anode electrode layer 140 may include known high work function materials such as anode metals that are substantially optically opaque, such as silver (Ag), gold (Au), and copper (Cu), for example, as well as suitable semiconductors and conductive polymers having suitable known work functions.

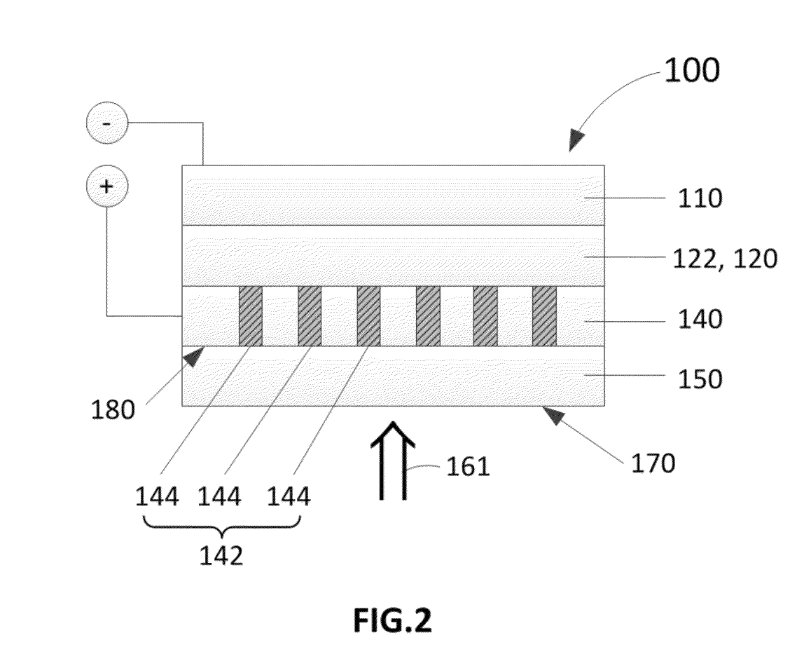

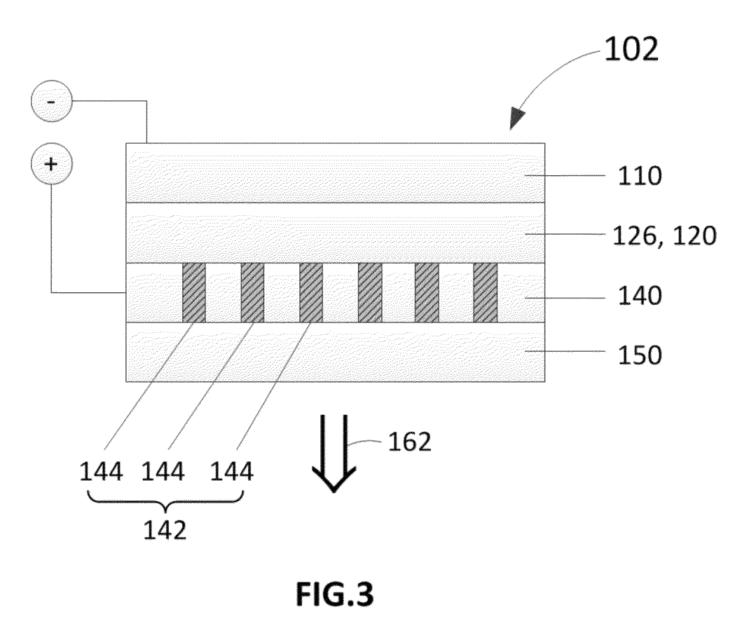

The organic electronic active region 120 of the OOD 100 includes one or more organic layers. The specific materials selected to form the organic layers of the organic electronic active region 120 depend on the particular construction of the OOD 100, which may be an OPV 101 or an OLED 102 as shown in respective FIGS. 2 and 3, for example, as discussed in further detail below.

The cathode electrode layer 110 of the OOD 100 may comprise of any suitable low work function cathode electrode materials, such as Indium (In), calcium/aluminum (Ca/Al), aluminum (Al), lithium fluoride (LiF), and aluminum oxide/aluminum (Al₂O₃/Al)), for example.

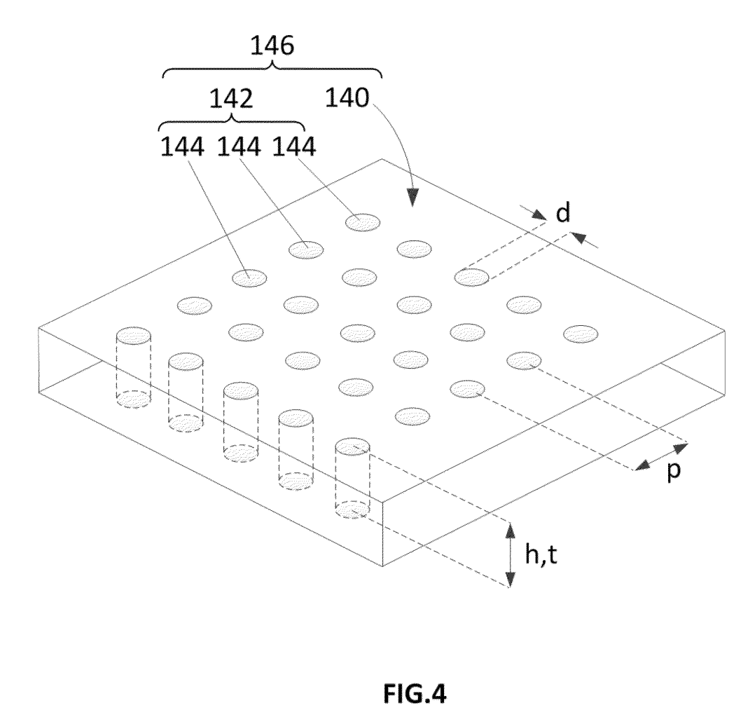

Referring to FIGS. 1 and 4, the latter being a perspective view of an exemplary metal anode electrode layer 140 of the OOD 100 (e.g. OPV 101 or OLED 102), according to one embodiment of the invention the metal anode electrode layer 140 has an ordered or periodic array 142 of sub-wavelength nanostructures (e.g. nanoholes 144) perforated therethrough. That is, the sub-wavelength nanoholes 144 are defined, formed, or fabricated in the metal anode electrode layer 140 and extend partially or fully through the thickness t thereof, thereby desirably controllably allowing for the selective transmission of light energy 160 through the nanoholes 144 formed in the metal anode electrode layer 140, which itself is otherwise, preferably, comprised of substantially optically opaque metal materials, such as silver (Ag), gold (Au), and copper (Cu). As such, the resulting metal anode electrode layer 140 formed with the periodic array 142 of sub-wavelength nanoholes 144, collectively forming the perforated metal anode electrode layer 146, provides as a highly conductive, optically-transmissive anode alternative to typical ITO and other transparent conductors employed in OODs, and desirably avoids the compromises and design and performance constraints associated with ITO, as discussed below.

As used herein, “sub-wavelength” nanostructures (e.g. nanoholes 144) refer to nanoholes and/or other nanostructures such as nano-slits or slots, where at least one geometric dimension of the nanostructures is less than a wavelength of the photons (e.g. sun light and/or artificial light) incident on the periodic array 142 at the interface 180 between metal anode electrode layer 140 and the carrier substrate 150.

Still referring to FIGS. 1 and 4, in a preferred embodiment, the nanoholes 144 may have substantially uniform dimensions, such as substantially circular and cylindrical shapes in two and three dimensions respectively, wherein the height h of the cylinder runs parallel with the thickness t of the metal anode electrode layer 140. Other geometric dimensions of sub-wavelength nanostructures, such as rectangular, triangular, polyhedral, elliptical, ovoid, linear, or irregular or wavy holes or openings, for example, may alternatively be selected in other embodiments.

The periodic array 142 of sub-wavelength nanoholes 144 may be formed in the metal anode electrode layer 140 by any suitable known technique capable of producing sub-wavelength nanoholes in a periodic pattern, such as by known milling techniques (e.g. focused ion beam (“FIB”) milling), lithography techniques (e.g. nano-imprint lithography, deep UV lithography, and electron beam lithography), hot stamping, and embossing, or combinations thereof, for example. In one embodiment, the nanoholes 144 may be defined in the metal anode electrode layer 140 using a FIB process such as by use of a Strata 235 Dualbeam Scanning Electron Microscope (“SEM”)/FIB. Gallium ions (Ga⁺) may be used as the FIB implantation source in one such embodiment, for example.

Having generally described the components of the OOD 100 according to the invention, the specific features of these components are now described in reference to the particular construction of the OOD 100.

### Organic Photovoltaic (“OPV”) Device 101

Referring to FIG. 2, a cross-sectional view of an OOD having the construction of an OPV device 101 (hereinafter “OPV 101”) according to an embodiment of the invention is provided. As shown in FIG. 2, in the embodiment in which the OOD is an OPV 101, the organic electronic active region 120 includes one or more organic layers. Specifically, in one embodiment, the organic active electronic region 120 includes an organic photoactive layer 122 disposed directly on the first electrode layer 120. The organic photoactive layer 122 is comprised of organic photoactive materials that in response to the absorption electromagnetic radiation (e.g. light 161), convert light energy to electrical energy.

In an optional embodiment, the organic active electronic region 120 may further include a hole transport layer (not shown) disposed between the anode electrode layer 140 and the photoactive layer 122, as known in the art. The hole transport layer is comprised of organic hole transport material that facilitates the transport of electron holes from the organic photoactive layer 122 to the anode electrode layer 140.

Suitable materials for the cathode electrode layer 110, the anode electrode layer 140, and the carrier substrate 150 of the OPV 101 may be similarly selected from the same list of exemplary materials for the respective corresponding layers as discussed above in connection with OOD 100.

In a preferred embodiment, the OPV 101 is a bulk heterojunction OPV, and exemplary organic photoactive materials of the organic photoactive layer 122 may include a photoactive electron donor-acceptor blend such as poly(3-hexylthiophene):[6,6]-phenyl-C₆₁-butyric acid methyl ester (P3HT:PCBM), for example. Exemplary hole transport materials for the hole transport layer may include conductive polymers, such as poly(3,4-ethylenedioxythiophene):poly(styrenesulfonate) (“PEDOT:PSS”), for example. However, it is understood that other suitable compounds may be employed as one or more exemplary organic photoactive materials in particular exemplary embodiments, such as PDCTBT (Poly[[9-(1-octylnonyl)-9H-carbazole-2,7-diyl]-2,5-thiophenediyl-2,1,3-benzothiadiazole-4,7-diyl-2,5-thiophenediyl]):PC70BM ([6,6]-phenyl-C₆₁-butyric acid methyl ester), or other suitable photoactive materials known in the art, for example.

In use, OPV 101 is configured to receive electromagnetic energy (e.g. light 161) incident to or at the underside or bottom side of OPV 101 as shown in FIG. 2, or more precisely, at a bottom major surface 170 of the carrier substrate 150, which is located opposite an interface 180 between the carrier substrate 150 and the anode electrode layer 140. Carrier substrate 150 is preferably substantially optically transparent in order to permit light 161 to propagate or transmit through the thickness of the carrier substrate 150 and arrive at the interface 180 between the carrier substrate 150 and the metal anode electrode layer 140. The interaction of surface plasmons (“SP”) with the light 161 in the form of photons at interface 180 causes selected portions of the light 161 to transmit through the nanoholes 144 and exhibit Extraordinary Optical Transmission (“EOT”) characteristics. The optical properties of the period nanohole array 142, including the wavelength of the peak optical transmission, the intensity of the transmitted light at the peak, and the optical transmission spectrum or bandwidth, may be desirably configured such that the enhanced transmission, or EOT, of the light 161 through the nanoholes 144 translates to an enhanced absorption of photons in the organic photoactive layer 122, which in turn relates to an overall increase in power and/or efficiency of the OPV 101.

In one embodiment, the peak optical transmission intensity and/or wavelength and the optical transmission bandwidth of the periodic array 142 may be configured to correspond or match the peak absorption intensity and/or wavelength and the optical absorption bandwidth of the photoactive layer 122, thereby ensuring the maximum amount of photons useful for photovoltaic conversion may be transmitted through the nanoholes 144 and be absorbed at the photoactive layer 122. In that sense, the periodic array 142 operates to enhance optical absorption at the photoactive layer 122, and functions as a spectral filter to filter or block harmful radiation, such as ultraviolet (UV) wavelengths, which have been shown to degrade the organic photoactive layer 122 and reduce the operational lifetime of the OPV 101.

Referring to FIGS. 2 and 4, the relationships between the geometric parameters of the nanoholes 144 and the periodic array 142 and the photonic or optical properties of the periodic array 142 are now described. Specifically, the desired periodicity p of the periodic array 142, or the distance from center to center of two neighbouring nanoholes 144, may depend at least in part on the desired peak optical transmission wavelength of the periodic array 142, the dielectric constant of the carrier substrate 150, and the dielectric constant of the metal anode electrode layer 140, based on the following first order approximation:

λ_{SP}(i,j)=p sqrt(eₘe_{d})/[sqrt(i²+j²)sqrt(e_{d}+eₘ)] (1)

In the above-noted equation, λ_{SPP}(i,j) is the (first order) peak optical transmission wavelength of the periodic array 142 or the peak wavelength of the SP resonance modes on the nanoholes 144 for a square lattice when the incident light 161 is normal to the plane of the periodic array 142; p is the periodicity of the array 142; e_{d} and eₘ are the dielectric constants of the metal-dielectric interface 180 and metal anode layer 140 respectively; and indices i and j are integers representing the peak orders.

Further, the desired geometry d and the desired depth or height h of each of said nanoholes 144 in the metal anode layer 140 (the latter of which corresponds to the thickness t of the metal anode electrode layer 140) are based or dependent on the desired optical transmission bandwidth of the periodic array 142, which in the case of an OPV 101 may be preferably selected to correspond to the optimal optical absorption bandwidth of the organic photoactive layer 122 as discussed above.

In a particular embodiment, the periodic array 142 as used in the OPV 101 may comprise nanoholes 144 each of which have a characteristic geometric dimension d of about 100 nanometers (nm), a height h in the metal anode layer 140 of about 105 nm, and a periodicity of about 450 nm. In other embodiments, the periodic array 142 of the OPV 101 may generally have a periodicity between about 400 nm and about 600 nm.

### Organic Light Emitting Diode (OLED 102)

FIG. 3 is a cross-sectional view of an OOD having the construction of an OLED 102, according to an embodiment of the invention.

As shown in FIG. 3, in an embodiment in which the OOD is an OLED 102, the organic active electronic region 120 may comprise one or more organic layers. In one embodiment, the organic active electronic region 120 may include an organic emissive electroluminescent layer 126 configured to emit electromagnetic radiation (e.g. light 162) in response to the passage of an electric current. The organic emissive electroluminescent layer 126 is disposed at least partially on an exemplary metal anode electrode layer 140 perforated with the periodic array 142 of sub-wavelength nanoholes 144.

Suitable materials for the organic emissive electroluminescent layer 126 may comprise any one of several known light-emitting dyes or dopants dispersed in a suitable host material, photosensitizing materials, and/or light-emitting polymer materials, for example.

In another embodiment, the organic active electronic region 120 may further include a hole transport layer (not shown) disposed at least partially between an exemplary metal anode electrode layer 140 and the emissive electroluminescent layer 126, as is known in the art. The hole transport layer may advantageously be provided to assist in the transfer of positive charges or “holes” from the metal anode electrode layer 140 to the emissive electroluminescent layer 126, for example. In other embodiments, the organic active electronic region 120 may include additional organic layers (not shown) advantageously provided to assist in the transfer of electrons from the cathode electrode layer 110 to the emissive electroluminescent layer 126, for example, as is known in the art.

Suitable materials for the cathode electrode layer 110, the anode electrode layer 140, and the carrier substrate 150 of the OLED 102 may be similarly selected from the same exemplary list of materials for the respective corresponding layers as discussed above in connection with OOD 100.

In use, the OLED 102 is configured such that upon application of an external electrical field on the electrode layers 110 and 150, the organic emissive electroluminescent layer 126 emits electromagnetic radiation, such as light 162. In one embodiment, the OLED 102 may be configured to be bottom emissive such that the light 162 emitted by the organic emissive electroluminescent layer 126 transmits through the nanoholes 144 in the metal anode electrode layer 140 and exits the OLED 102 through the carrier substrate 150 to thereby effect illumination. The optical transmission properties of the periodic nanohole array 142, including the wavelength of the peak optical transmission, the intensity of the transmitted light at the peak, and the optical transmission bandwidth, may be desirably configured such that the optical transmission properties (e.g. optical transmission spectrum) of the periodic nanohole array 142 corresponds to or matches with the optical emission properties (e.g. the optical emission spectrum) of the organic emissive electroluminescent layer 126, such that the specific wavelengths (colors) at which the light 162 is emitted by the organic emissive electroluminescent layer 126 may transmit through the otherwise optically opaque metal anode electrode layer 140, thereby resulting in an ITO-free OLED 102 based on a metal anode electrode layer 140 perforated with a periodic array 142 of nanoholes 144 that is desirably lower in cost and better protected from the effects of moisture and oxygen diffusion on the organic layers and desirably also enjoys an overall increase in device performance, as compared to a conventional ITO-OLED.

In one embodiment, the optical transmission properties of the periodic nanohole array 142 of the OLED 102 may be configured such that the intensity of the light 162 emitted by the organic emissive electroluminescent layer 126 and transmitted through the nanoholes 144 is enhanced, thereby resulting in an increased apparent “brightness” in OELD 102 illumination. Such enhanced optical emission may be achieved by configuring the optical transmission properties of the periodic nanohole array 142 of the OLED to match with or correspond to the similar optical emission properties of the organic emissive electroluminescent layer 126 (e.g. wavelength of the peak optical emission, the intensity of the emitted light at the peak, and the optical emission bandwidth).

The desired periodicity p of the periodic array 142 of the OLED 102 may similarly be governed by equation (1) as discussed above in connection with OPV 101.

The desired geometric dimension d and the desired depth or height h of each of said nanoholes 144 in the metal anode layer 140 of the OELD 102 are similarly based or dependent on the desired optical transmission bandwidth of the periodic array 142, which in the case of an OLED 102 may be desirably selected to correspond with the optical emission bandwidth of the organic emissive electroluminescent layer 126 as discussed above.

In an alternative embodiment, an OOD according to an embodiment of the present invention may comprise an inverse configuration wherein a cathode layer is disposed at least partially on a suitable carrier substrate, a suitable organic electronic active region (which may comprise at least one of an active layer and a hole transport layer) is disposed at least partially on the cathode layer, and an anode layer is disposed at least partially on the organic photoactive layer.

### Exemplary Geometries and Patterns of Nanostructures

The geometries and arrangement patterns of the sub-wavelength nanostructures formed in the metal anode electrode layer 140 may depend, at least in part, on the intended use of the organic optoelectronic device 100 and the desired optical transmission properties of the sub-wavelength nanostructures. In one embodiment, for example, sub-wavelength nanostructures may comprise substantially circular holes, such as nanoholes 144 as described above in reference to FIG. 1, or alternately holes or openings of other geometric shapes having at least one sub-wavelength geometric dimension, such as rectangular, triangular, polyhedral, elliptical, ovoid, or irregular or wavy holes or openings, for example, which may be arranged in one or more periodic patterns such that the sub-wavelength nanostructures display a desired optical transmission property, for example. In another embodiment, the sub-wavelength nanostructures may comprise substantially elongated openings, such as lines, slits, arced, or curved openings, for example, and which may optionally be oriented substantially parallel to each other to provide a grating, such as a nano-feature grating, for example. In yet another embodiment, the sub-wavelength nanostructures may comprise features having at least sub-wavelength dimension, in the metal anode electrode layer 140, such as cantilevers, grooves, bumps, bosses, indents, or waves, for example, for which there may optionally be no opening extending through the metal anode electrode layer 140.

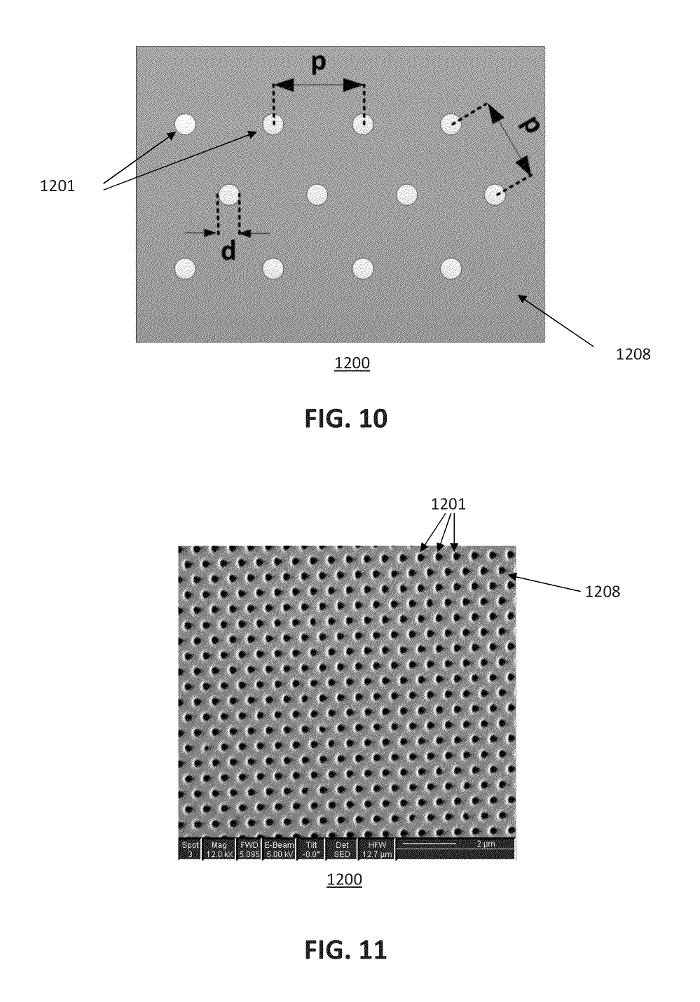

Embodiments of the sub-wavelength nanostructures configured with additional exemplary periodic patterns and geometries are now described with reference to FIGS. 10-17. These exemplary sub-wavelength nanostructures may be adapted to be formed in a metal anode electrode layer of an OLED, OPV or other OODs of the present invention by any suitable known method or process. FIGS. 10 and 11 illustrate a schematic view and a scanning electron microscope (SEM) image of the sub-wavelength nanostructures arranged in a first exemplary periodic pattern 1200 according to an embodiment of the invention. In the embodiment as shown in FIG. 10, exemplary sub-wavelength nanostructures comprise a plurality of nanoholes 1201 organized in a periodic array or pattern 1200 and formed in a metal anode electrode layer 1208. The method of forming sub-wavelength nanostructures (nanoholes 1201) in the metal anode electrode layer 1208, and characteristics of the metal anode electrode layer 1208 may be similar to that of the metal anode electrode layer 140 discussed above with reference to FIG. 1. As compared to the nanoholes 144 shown in FIG. 4 arranged in the periodic array 142, which has a square lattice configuration, nanohole 1201 are arranged in the periodic array or pattern 1200 of a hexagonal lattice configuration. Exemplary nanoholes 1201 each have a geometric dimension (such as their diameter) of less than a wavelength of the light incident on, reflected by, or transmitted through nanoholes 1201. For example, nanoholes 1201 may each have a diameter d of approximately 150 nm and may preferably be equally spaced apart from one another with a spacing, pitch, or periodicity p, of 650 nm, for example.

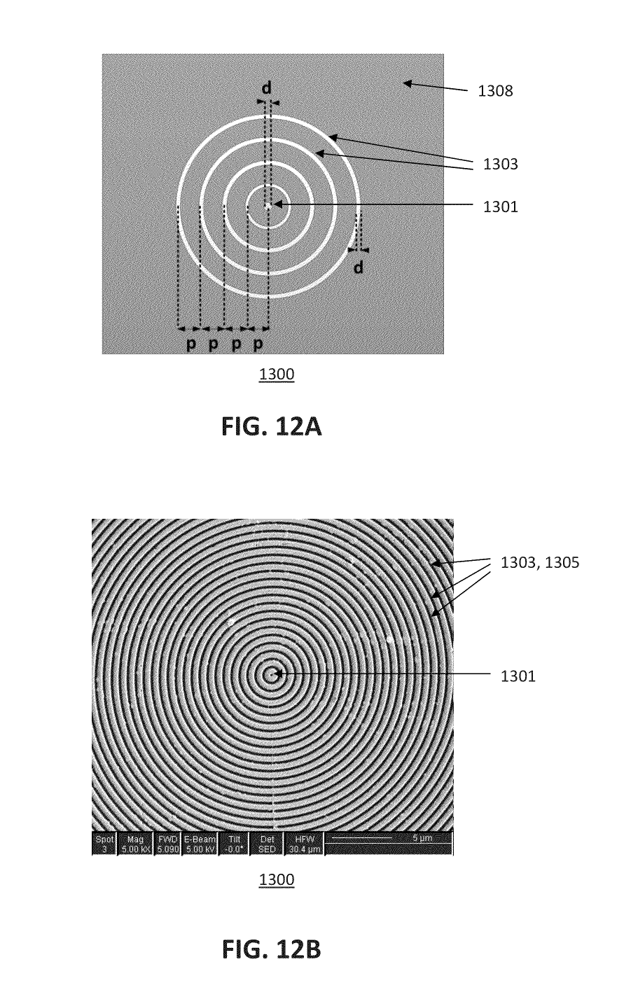

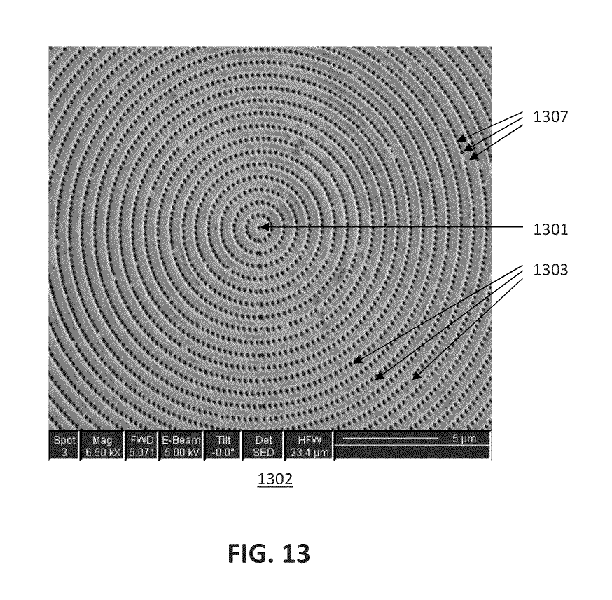

FIGS. 12A and 12B illustrate a schematic view and a SEM view of the sub-wavelength nanostructures arranged in a second exemplary periodic pattern 1300 respectively, according to another embodiment of the invention. In this embodiment, periodic pattern 1300 is a circular periodic pattern 1300 which includes a central hole or opening 1301 having at least one geometric dimension that is sub-wavelength in size relative to a wavelength of light incident on the central hole 1301. Exemplary geometric shapes of the central hole 1301 may include circular, rectangular, triangular, polyhedral, elliptical, ovoid, or irregular or wavy holes or openings, for example. In the embodiment as shown in FIGS. 12A and 12B, the central hole 1301 is a substantially circular nanohole. The circular nanohole 1301 may have a diameter d that is sub-wavelength in size relative to a wavelength of light incident on circular nanohole 1301, such as a diameter d of 150 nm, for example. The second periodic pattern 1300 further includes a plurality of annular rings 1303 concentrically disposed about the central hole 1301. Preferably, an appropriate number of the annular rings 1303 may be selected such that the second periodic pattern 1300 spans substantially the entire surface of a metal anode electrode layer 1308 on which the second periodic pattern 1300 is formed. The annular rings 1303 may be disposed relative to each other and to the central hole 1301 with a spacing or periodicity p of approximately 650 nm, for example. The width of the annular rings 1303 may be configured to be sub-wavelength in size relative to a wavelength of light incident on the annular rings 1303, and may be further configured to have the same dimension as the diameter d of the central hole 1301, such as approximately 150 nm, for example. In one embodiment, the annular rings 1303 are formed by annular holes or openings 1305, as best shown in FIG. 13B. In an alternative embodiment, however, annular rings 1303 may be formed by nanoholes arranged in a plurality of rings concentrically disposed about the central hole 1301, as shown in FIG. 13.

FIG. 13 illustrates a SEM view of the sub-wavelength nanostructures arranged in a third exemplary periodic pattern 1302, according to an embodiment of the invention. Similar to the embodiment shown in FIG. 12B, the third periodic pattern 1302 according to the embodiment as shown in FIG. 13 includes a central hole or opening 1301. Unlike the embodiment shown in FIG. 12B, however, the annular rings 1303 in the alternative embodiment shown in FIG. 13 are formed by a plurality of nanoholes 1307 arranged in a plurality of rings concentrically disposed about the central hole 1301. The nanoholes 1307 and central hole 1301 each have a diameter d that is sub-wavelength in size relative to a wavelength of light incident on the nanoholes 1307, such as a diameter d of 150 nm, for example. The annular rings 1303 of nanoholes 1307 may be disposed relative to each other and to the central hole 1301 with a spacing or periodicity p of approximately 650 nm, for example.

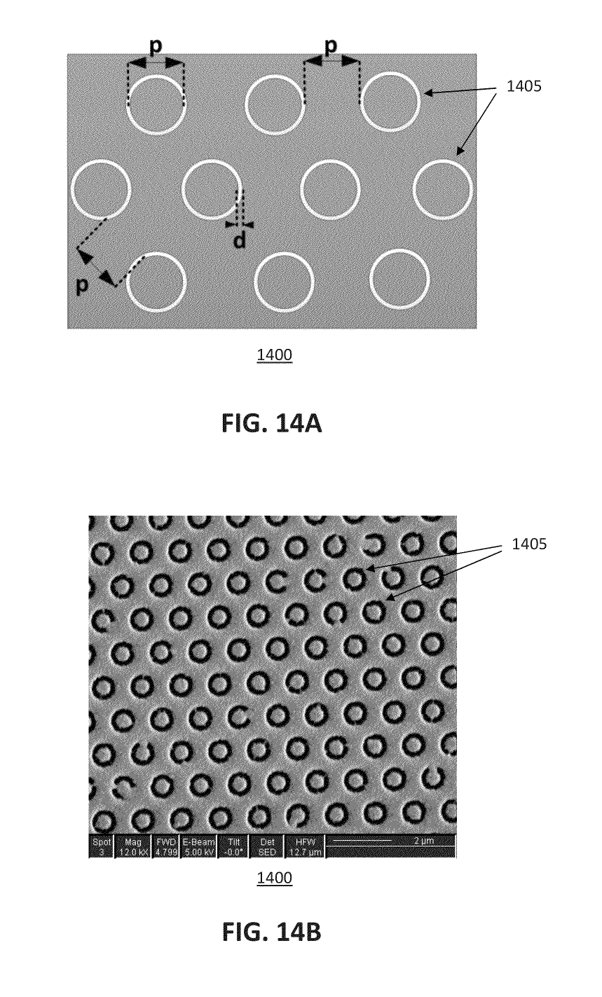

FIGS. 14A and 14B illustrate a schematic view and an SEM view of exemplary sub-wavelength nanostructures arranged in a fourth exemplary periodic pattern 1400 respectively, according to an embodiment of the invention. In this embodiment, the periodic pattern 1400 includes a plurality of annular holes or openings 1405 disposed in a hexagonal lattice configuration. Other periodic patterns for arranging the annular openings 1405 may be selected however, such as hexagonal, square, rhombic, rectangular, and parallelogrammatic lattice, for example. The width d of the annular openings 1405 may be configured to be sub-wavelength in size relative to a wavelength of light incident on the annular openings 1405, such as approximately 150 nm, for example. The annular openings 1405 may preferably be equally spaced apart from one another with a spacing, pitch, or periodicity p, of 650 nm, for example.

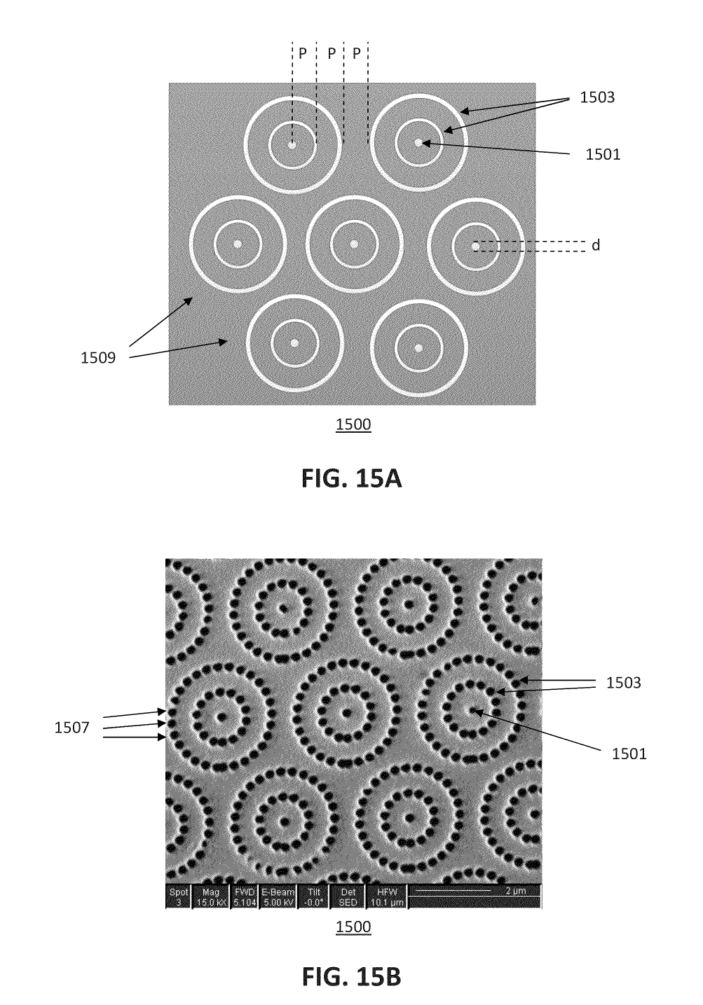

FIGS. 15A and 15B illustrate a schematic view and an SEM view of the sub-wavelength nanostructures arranged in a fifth exemplary periodic pattern 1500 respectively, according to an embodiment of the invention. In this embodiment, the fifth periodic pattern 1500 includes a plurality of central holes or openings 1501 each having at least one geometric dimension that is sub-wavelength in size relative to a wavelength of light incident on the central holes 1501. Exemplary geometric shapes of the central holes 1501 include circular, rectangular, triangular, polyhedral, elliptical, ovoid, or irregular or wavy holes or openings, for example. In the embodiment as shown in FIGS. 15A and 15B, the central holes 1501 are substantially circular nanoholes. The circular nanoholes 1501 may each have a diameter d that is sub-wavelength in size relative to a wavelength of light incident on circular nanohole 1501, such as a diameter d of 150 nm, for example. The fifth periodic pattern 1500 further includes a plurality of pairs of annular rings 1503. Each pair of annular rings 1503 corresponds to a unique central hole 1501 and is concentrically disposed about this corresponding central hole 1501. Each pair of the annular rings 1503 may be disposed relative to each other and to their corresponding central hole 1501 with a spacing or periodicity p of approximately 650 nm, for example. The width of the annular rings 1503 may be configured to be sub-wavelength in size relative to a wavelength of light incident on the annular rings 1503, and may be further configured to have the same dimension as the diameter d of the central holes 1501, such as approximately 150 nm, for example. In the embodiment as shown in FIG. 15B, the annular rings 1503 are formed by nanoholes 1507 arranged in a pair of rings concentrically disposed about its corresponding central hole 1501. In an alternative embodiment (not shown), however, each pair of the annular rings 1503 may be formed by annular holes or openings 1507, similar to the embodiment as shown in FIG. 12B where annular rings 1303 are formed by annular openings 1305 in concentric rings. As used herein, each pair of annular rings 1503 with its corresponding central hole 1501 is defined as a unitary cell 1509, such that the fifth periodic pattern 1500 can be said to be comprised of a plurality of periodically arranged unitary cells 1509. In the embodiment as shown, the unitary cells 1509 are arranged in a hexagonal lattice configuration. Other periodic patterns for arranging the unitary cells 1509 may be selected however, such as a hexagonal, square, rhombic, rectangular, and parallelogrammatic lattice, for example.

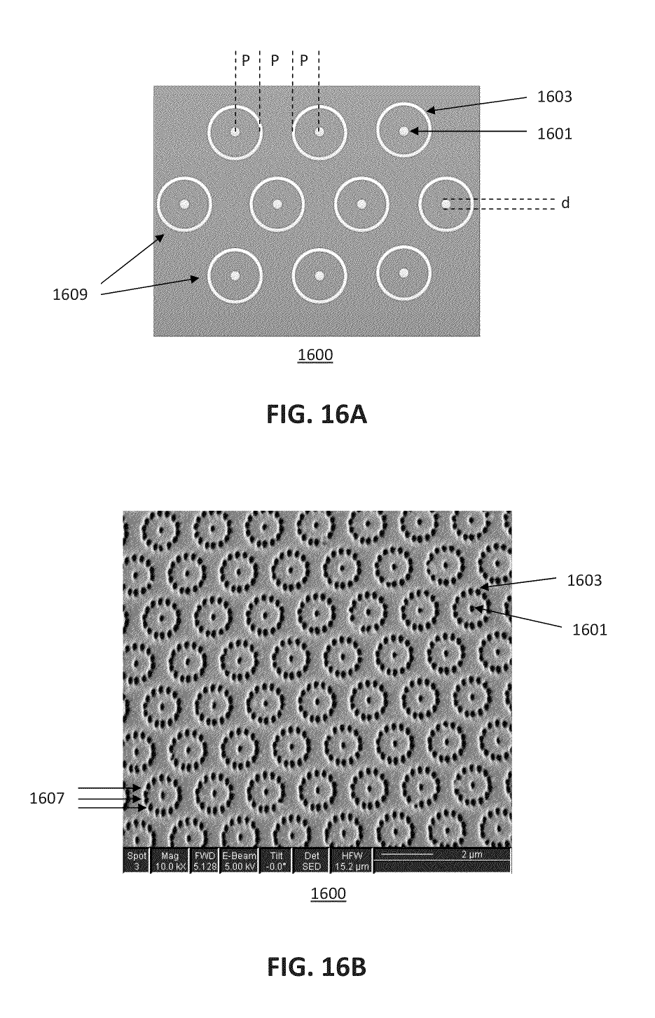

FIGS. 16A and 16B illustrate a schematic view and an SEM view of the sub-wavelength nanostructures arranged in a sixth exemplary periodic pattern 1600 respectively, according to an embodiment of the invention. In this embodiment, the sixth periodic pattern 1600 includes a plurality of central holes or openings 1601 having at least one geometric dimension that is sub-wavelength in size relative to a wavelength of light incident on central hole 1601. Exemplary geometric shapes of central holes 1601 include circular, rectangular, triangular, polyhedral, elliptical, ovoid, or irregular or wavy holes or openings, for example. In the embodiment as shown in FIGS. 16A and 16B, each of the central holes 1601 is a substantially circular nanohole. The circular nanoholes 1601 may each have a diameter d that is sub-wavelength relative to a wavelength of light incident on circular nanoholes 1601, such as a diameter d of 150 nm, for example. The sixth periodic pattern 1600 further includes a plurality of annular rings 1603 each corresponding to a unique circular nanohole 1601. Each of the annular rings 1603 is concentrically disposed about its corresponding central hole 1601. Annular rings 1603 may be disposed relative to their corresponding central holes 1601 and to the neighbouring annual rings 1603 with a spacing or periodicity p of approximately 650 nm, for example. The width of annular rings 1603 may be configured to be sub-wavelength in size relative to a wavelength of light incident on annular rings 1503, and may be further configured to have the same dimension as the diameters d of central holes 1501, such as approximately 150 nm, for example. In the embodiment as shown, the annular ring 1603 and circular nanohole 1601 pairs are arranged in a hexagonal lattice configuration. Other periodic patterns for arranging the annular ring 1603 and circular nanohole 1601 pairs may be selected however, such as hexagonal, square lattice, rhombic, rectangular, and parallelogrammatic lattice, for example.

Preferably, each of the annular rings 1603 are formed by a plurality of nanoholes 1607 arranged in a single ring concentrically disposed about its corresponding central hole 1601, similar to the manner the annular rings 1303 are formed by arranging nanoholes 1307 in concentric rings as shown in FIG. 13. In an alternative embodiment, however, each of the annular rings 1603 may be formed by a single annular hole or opening (not shown) concentrically disposed about its corresponding central hole 1601 (not shown), similar to the embodiment as shown in FIG. 12B, where the annular rings 1303 are formed by concentrically disposed annular openings 1305.

As described herein, each annular ring 1603 with its corresponding central hole 1601 may be defined as a unitary cell 1609, such that the periodic pattern 1600 can be said to be comprised of a plurality of periodically arranged unitary cells 1609. In the embodiment as shown, the unitary cells 1609 are arranged in a hexagonal lattice configuration. Other periodic patterns for arranging the unitary cells 1609 may be selected however, such as a hexagonal, square, rhombic, rectangular, and parallelogrammatic lattice, for example.

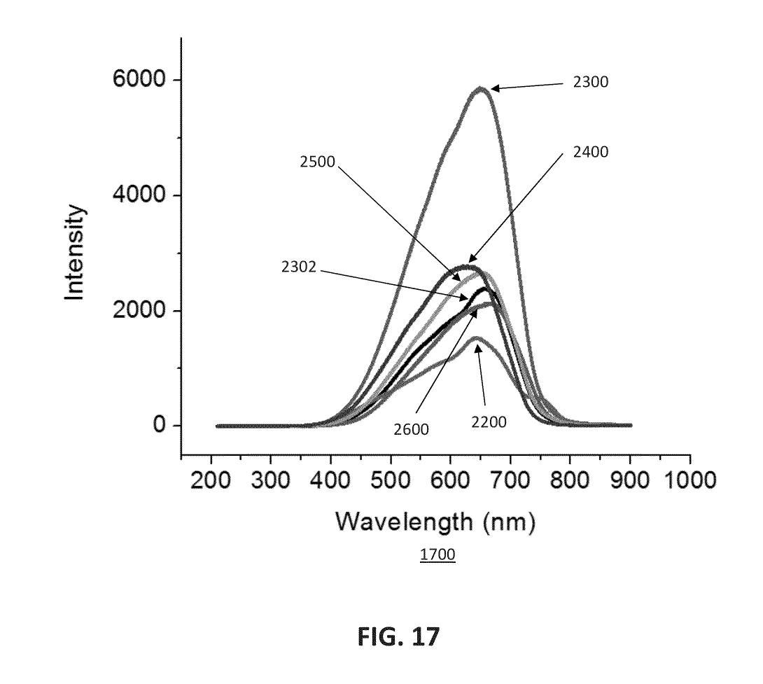

FIG. 17 illustrates a spectrogram plot 1700 of the sub-wavelength nanostructures with periodic patterns 1300, 1400, 1302, 1500, 1600, and 1200, which correspond to spectrogram curves 2300, 2400, 2302, 2500, 2600, and 2200, respectively. As generally observed in FIG. 17, arranging sub-wavelength nanostructures in different periodic patterns 1300, 1400, 1302, 1500, 1600, and 1200 causes the light transmitted through the subwavelength nanostructures to have different bandwidths and intensities. Therefore, depending on the bandwidth and/or intensity at which the light transmitted through the sub-wavelength nanostructures is desired, a suitable periodic pattern for arranging sub-wavelength nanostructures may be selected. Accordingly, embodiments of the present invention provides tunability in the optical transmission properties of the sub-wavelength nanostructures, which when adapted to be formed in a metal anode electrode layer of an OOD of the present invention, may desirably enhance the performance thereof.

For example, in one embodiment where the sub-wavelength nanostructures are adapted to be formed in a metal anode electrode layer of an OLED (e.g. OLED 102 of FIG. 3) of the present invention, the light emitted by the OLED 102 may be desired to have a “sharper” color from the perspective of a person observing the OLED 102. In such embodiment, the sub-wavelength nanostructures may be configured with a suitable periodic pattern, such as periodic patterns 1200 (corresponding to curve 2200) and 1302 (curve 2302), such that the light emitted by the organic emissive electroluminescent layer 126 of the OLED 102, upon transmission through the sub-wavelength nanostructures in the metal anode electrode layer of the OLED 102, is altered or tuned to have a relatively narrow bandwidth which corresponds to a “sharper” color from the perspective of a person observing the OLED 102.

Similarly, if the light emitted by the OLED 102 is desired to have a specific, predefined wavelength(s), the sub-wavelength nanostructures may be configured with a suitable periodic pattern, such as periodic patterns 1200 (curve 2200) and 1302 (curve 2302), such that the light emitted by the organic emissive electroluminescent layer 126, upon transmission through the sub-wavelength nanostructures, is altered or tuned to have a relatively narrow bandwidth corresponding to the desired, predefined wavelength(s).

In another embodiment where the light emitted by the OLED 102 is not required to have a specific, predefined wavelength(s), the sub-wavelength nanostructures may be arranged in a suitable periodic pattern, such as periodic patterns 1300 (curve 2300), such that the light emitted by the organic emissive electroluminescent layer 126, upon transmission through the sub-wavelength nanostructures, is altered or tuned to have a relatively high illumination intensity, which may desirably correspond to an effective overall increase in efficiency of the OLED 102.

In one embodiment where the sub-wavelength nanostructures are adapted to be formed in a metal anode electrode layer of an OPV (e.g. OPV 101 of FIG. 2) of the present invention, the sub-wavelength nanostructures may be arranged in a suitable periodic pattern, such as periodic patterns 1300 (curve 2300), such that light 161 incident on the OPV 101, upon transmission through the sub-wavelength nanostructures in the metal anode electrode layer 140, is tuned or altered to have a relatively high illumination intensity corresponding to an enhanced optical transmission, which translates to an enhanced absorption of photons in the organic photoactive layer 122 of the OPV 101 available for photovoltaic conversion, thereby effectively increasing the overall power and/or efficiency of the OPV 101.

In one embodiment where the OPV 101 has a low band gap, and therefore has a relatively wider spectrum of photon absorption, the sub-wavelength nanostructures may be similarly configured to have a relatively wide optical transmission spectrum to match the absorption spectrum of the organic photoactive layer 122 of the OPV 101, such that the maximum amount of useful photons are exploited to improve the overall power and/or efficiency of the OPV 101. In such embodiment, the sub-wavelength nanostructures may be arranged in a suitable periodic pattern, such as periodic patterns 1300, 1400, 1500, 1600 (corresponding to spectrogram curves 2300, 2400, 2500, 2600, respectively), such that light 161 incident on the OPV 101, upon transmission through the sub-wavelength nanostructures in the metal anode electrode layer 140, is tuned or altered to have the desired relatively wide transmission spectrum.

### Method of Manufacturing an OOD

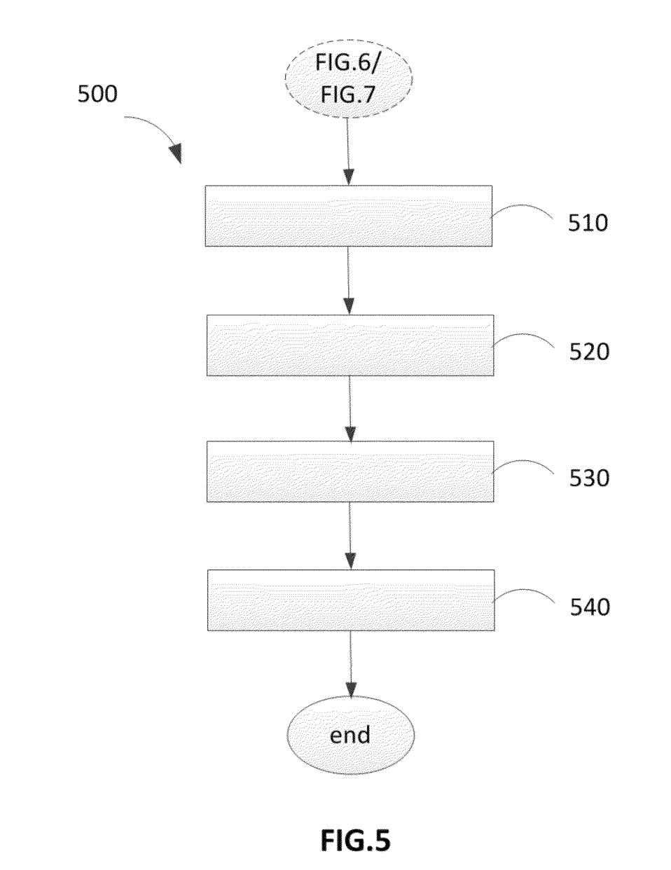

Referring now to FIG. 5, a flow diagram of a method 500 of manufacturing an OOD according to an exemplary embodiment of the invention is shown. The method 500 according to this exemplary embodiment may be adapted to manufacture an OOD 100 such as that shown in FIG. 1, and may be particularly adapted to manufacture any one desired type of OOD, such as an OPV (e.g. OPV 101 shown in FIG. 2), or an OLED (e.g. OLED 102 shown in FIG. 3), for example. The method 500 in this exemplary embodiment begins with forming a metal anode electrode layer 140 on a carrier substrate 150, as shown at operation 510. In one such embodiment, the substrate carrier 150 may be in the form of a sheet or continuous film. The continuous film can be used, for example, for providing roll-to-roll continuous manufacturing processes according to the present invention, as may be particularly desirable for use in a high-volume manufacturing environment. In an exemplary embodiment of the method 500 adapted for OPV 101 fabrication, carrier substrate 151 (e.g. glass slide or flexible polyethylene terephthalate (“PET”)) may first be pretreated prior to the deposition or formation of metal anode electrode layer 140 thereon. For example, glass slide or PET substrate 150 may be pretreated by thorough sonication in acetone, 2-propanol (“IPA”) and deionized water (“DI”) for ten (10) minutes each, and then dried with nitrogen (N₂).

The metal anode electrode layer 140 may be formed on the carrier substrate 150 by any suitable means or method so as to deposit, attach, adhere or otherwise suitably join the metal anode electrode layer 140 to at least a portion of the top surface of the carrier substrate 150. In one embodiment, the metal anode electrode layer 140 may be formed on the carrier substrate 150 by any suitable deposition techniques, including physical vapor deposition, chemical vapor deposition, epitaxy, etching, sputtering and/or other techniques known in the art and combinations thereof, for example. Typical anode materials for the metal anode electrode layer 140 are listed above in the section for the “OOD 100” with reference to FIG. 1.

In an exemplary embodiment of the method 500 adapted for OPV 101 fabrication, the anode material for the metal anode electrode layer 140 is selected from thin films of chromium (Cr)/silver (Ag) with thickness of 5 nm and 100 nm, respectively, and are deposited on the carrier substrate 150 by sputtering.

Next, the method 500 proceeds with forming a periodic array 142 of sub-wavelength nanostructures (e.g. nanoholes 144) in the metal anode electrode layer 140, as shown at operation 520. As discussed above, the periodic array 142 of sub-wavelength nanoholes 144 may be formed in the metal anode electrode layer 140 by any suitable known technique capable of producing sub-wavelength nanoholes in a periodic pattern, such as known milling techniques (e.g. focused ion beam (“FIB”) milling), lithography techniques (e.g. nano-imprint lithography, deep UV lithography, and electron beam lithography), hot stamping, and embossing, or the combinations thereof, for example. In an exemplary embodiment of the method 500 adapted for OPV 101 fabrication, nanoholes 144 fabrication is performed using FIB milling, such as with a Strata™ 235 Dualbeam Scanning Electron Microscope (“SEM”)/Focused Ion-Beam (“FIB”). Multiple periodic arrays 142 of approximately 100 nm in geometry and with 450 nm periodicity are then milled into the 105 nm metal anode layer 140 (e.g. film) using a Gallium ion (Ga⁺) source of the FIB. Nanohole areas of approximately 1 mm² are subsequently created by serially milling multiple 625 μm² periodic arrays 142 at a magnification of ×5000.

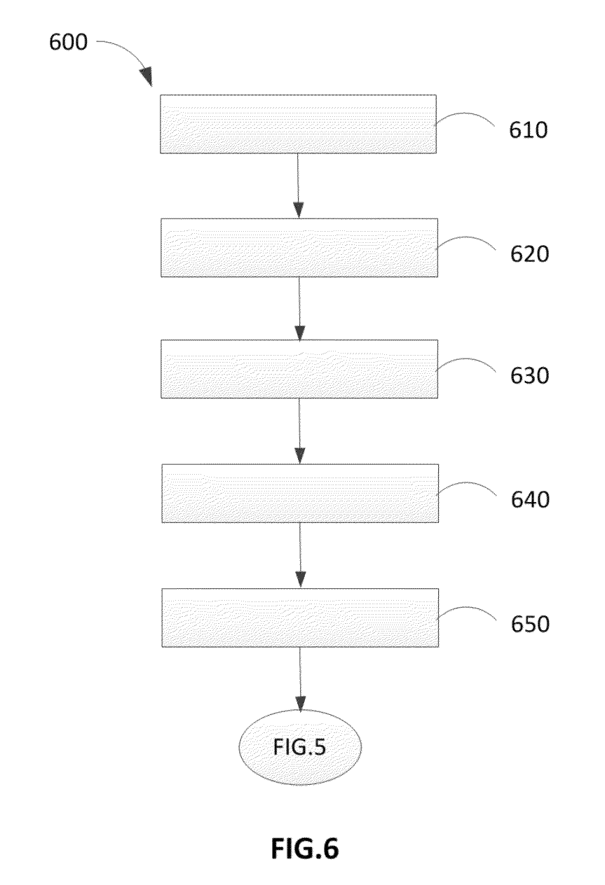

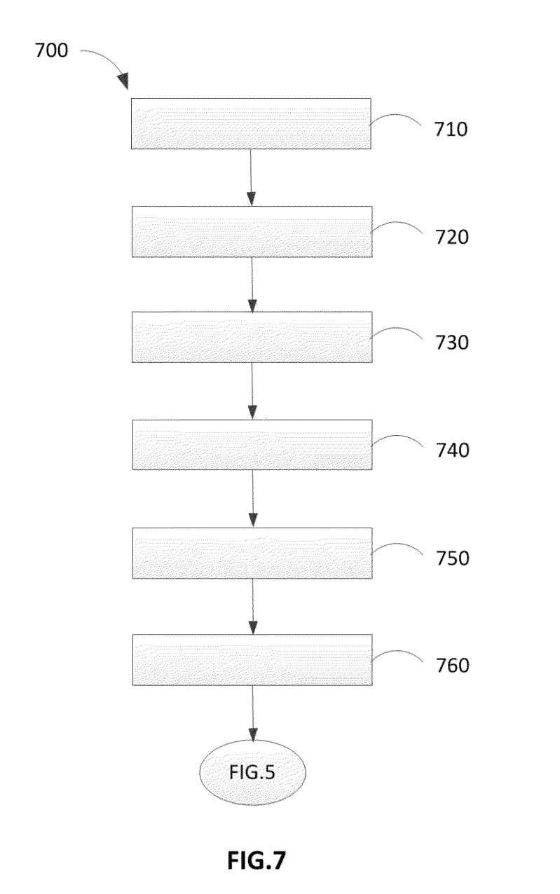

The particular geometrical parameters of the periodic array 142 (e.g. periodicity p) and the nanoholes 144 (e.g. hole geometry d and hole height h) may be pre-defined prior to the commencement of the method 500, and may be pre-defined according to the preliminary steps for the fabrication of an OPV 101 as illustrated in FIG. 6, and according to the preliminary steps for the fabrication of an OLED 102 as illustrate in FIG. 7, and are later discussed in detail below.

In some embodiments, the method 500 may additionally include a baking or annealing step, which may optionally be conducted in a controlled atmosphere, such as to optimize the photo-conversion of the organic active region 122, for example.

Next, as shown at operation 530, the method 500 proceeds to forming an organic electronic active region 120 on the perforated metal anode electrode layer 146. The organic electronic active region 120 includes one or more organic layers.

In one embodiment in which the method 500 is particularly adapted to optimally manufacture an OPV (e.g. OPV 101), the organic electronic active region 120 includes a photoactive layer 122. The operation 530 of forming an organic electronic active region 120 on the metal anode electrode layer 140 includes forming the organic photoactive layer 122 on the perforated metal anode electrode layer 146. The organic photoactive layer 122 may be formed on the perforated metal anode electrode layer 146 at operation 530 by any suitable organic film deposition techniques, including, but not limited to, spin coating, spraying, printing, brush painting, molding, and/or evaporating on a photoactive material on the perforated metal anode electrode layer 146 to form the organic photoactive layer 122, for example. Exemplary suitable organic photoactive materials are listed above in the section for the “OPV 101” with reference to FIG. 2. In an exemplary embodiment of the method 500 adapted for OPV 101 fabrication, the organic photoactive layer 122 is a poly(3-hexylthiophene):[6,6]-phenyl-C₆₁-butyric acid methyl ester (P3HT:PCBM) blend, and may be prepared by dissolving 10 mg/ml of P3HT and 8 mg/ml of PCBM separately in chlorobenzene (anhydrous) and stirred for approximately 12 hours at room temperature in air. The P3HT:PCBM (1:0.8) blend is then made by mixing the two chlorobenzene solutions, followed by stirring with a magnetic stirrer at 45° C. for approximately 12 hours in air. The obtained P3HT:PCBM active polymer solution is subsequently filtered with a 0.45 μm polypropylene (“PP”) syringe filter in order to remove any undissolved cluster.

In one embodiment in which the method 500 is particularly adapted to manufacture an OLED (e.g. OLED 102), the organic electronic active region 120 includes an organic emissive electroluminescent layer 126. The operation 530 of forming an organic electronic active region 120 on the metal anode electrode layer 140 alternatively includes forming the organic emissive electroluminescent layer 126 on the perforated metal anode electrode layer 146. The organic emissive electroluminescent layer 126 may similarly be formed on the perforated metal anode electrode layer 146 at operation 530 by any suitable organic film deposition techniques, including, but not limited to, spin coating, spraying, printing, brush painting, molding, and/or evaporating on a photoactive material on the perforated metal anode electrode layer 146 to form the organic emissive electroluminescent layer 126, for example. Exemplary suitable materials for the organic emissive electroluminescent layer 126 may comprise any one of several known light-emitting dyes or dopants dispersed in a suitable host material, photosensitizing materials, and or light-emitting polymer materials, for example, as are known in the art.

Following the formation of the organic electronic active region 120 on the perforated metal anode electrode layer 140 at operation 530, the method 500 proceeds to operation 540 at which a cathode electrode layer 110 is formed at least partially on the organic electronic active region 120, thereby completing the fabrication of the OOD 100. Similar to the metal anode electrode layer 140, the cathode electrode layer 110 may be formed on the organic electronic active region 120 by any suitable means or method so as to deposit, attach, adhere or otherwise suitably join the cathode electrode layer 110 to at least a portion of the top surface of the organic layer(s) of the organic electronic active region 120. In one embodiment, the cathode electrode layer 110 may be formed on the organic electronic active region 120 by any suitable deposition techniques, including physical vapor deposition, chemical vapor deposition, epitaxy, etching, sputtering and/or other techniques known in the art and combinations thereof, for example.

In an exemplary embodiment of the method 500 adapted for OPV 101 fabrication, the cathode electrode layer 110 is made of aluminum with preferably a thickness of approximately 100 nm, and is deposited on the P3HT:PCBM organic photoactive layer 122 by thermal evaporation.

Other method embodiments of the method 500 of manufacturing an OOD have been contemplated. For example, in an embodiment in which the method 500 is particularly adapted to manufacture an OPV (e.g. OPV 101 shown in FIG. 2), the organic electronic active region 120 may optionally include a hole transport layer (not shown) in addition to the organic photoactive layer 122, as known in the art. In such an embodiment, the operation 530 of the method 500 of forming an organic electronic active region 120 on the perforated metal anode electrode layer 146 alternatively includes the sub-steps of first forming the hole transport layer on the perforated metal anode electrode layer 146, followed by forming the organic photoactive layer 122 on the hole transport layer, after which the method 500 proceeds to step 540 to form the cathode electrode layer 110 on the organic electronic active region (the organic photoactive layer 122) as disused above. In an exemplary embodiment of the method 500 adapted for OPV 101 fabrication, the hole transport layer includes one or more conductive polymers, such as PEDOT:PSS, and the organic photoactive layer 122 is a photoactive electron donor-acceptor blend such as (P3HT:PCBM). The PEDOT:PSS may be spin coated on the perforated anode electrode layer 146 at, optimally, about 2000 rpm in air. The PEDOT:PSS may be filtered using 0.45 μm syringe filters prior to its deposition. The P3HT:PCBM is then subsequently spin-casted at, optimally, about 700 rpm in air on top of the PEDOT:PSS layer. Preferably, prior to P3HT:PCBM deposition on the PEDOT:PSS layer, the sample is transferred onto a hotplate and dried at 110° C. in air for 20 minutes. After P3HT:PCBM deposition on the PEDOT:PSS layer, the resulting sample is then preferably covered with a petri-dish and allowed to dry for, optimally, 20 minutes in air prior to cathode deposition at step 540.

In some embodiments, prior to the commencement of the method 500 as shown in FIG. 5 at operation 510, the method 500 of manufacturing an OOD may further include preliminary configuration steps for pre-defining the geometric parameters of the periodic array 142 and the sub-wavelength nanoholes 144, as shown in FIG. 6.

Referring to FIG. 6, the preliminary configuration steps for pre-defining the geometrical parameters of the periodic array 142 and the sub-wavelength nanoholes 144 and particularly adapted for optimal fabrication of the OPV 101 are shown. As noted above, the optical properties of the periodic array 142 are preferably defined to match or correspond with the optical properties of the organic photoactive layer 122 in the OPV 101 to thereby allow the incident light 161 (FIG. 2) to undergo enhanced transmission through the nanoholes 144 for optimal absorption at the organic photoactive layer 122. The steps as shown in FIG. 6 may be performed to affect such enhanced photonic absorption.

As shown in FIG. 6, the preliminary steps for pre-defining the geometric parameters of the periodic array 142 and the sub-wavelength nanoholes 144 begins at operation 610, at which a peak optical absorption wavelength of the organic photoactive layer 122 to be formed at least partially on the metal anode electrode layer 140 is determined. In an exemplary embodiment of OPV 101 fabrication, the organic photoactive layer 122 may be selected to be a P3HT:PCBM blend, which is determined at operation 610 to have a peak optical absorption wavelength of about 500 nm corresponding to the green region of the visible spectrum.

Next, at operation 620, a desired peak optical transmission wavelength of the periodic array 142 adapted to be formed in the metal anode electrode layer 140 is defined based on the peak optical absorption wavelength of the organic photoactive layer 122 determined at operation 610. In an exemplary embodiment of OPV 101 fabrication, the metal anode electrode layer 140 is selected to be a silver anode layer. Therefore, at operation 620, a desired peak optical transmission wavelength of the periodic array 142 adapted to be formed in this silver metal anode electrode layer 140 is defined to preferably match the peak optical absorption wavelength of the organic photoactive layer 122 determined at operation 620, or 500 nm.

Following operation 620, a desired periodicity p of the periodic array 142 is determined at operation 630 based at least in part on the desired peak optical transmission wavelength of the periodic array 142 determined at 620, a dielectric constant of the carrier substrate 150, and a dielectric constant of the metal anode electrode layer 140. The periodicity of the periodic array 142 may be determined based on the first order approximation of the peak optical transmission wavelength λ_{SP}(i,j) of the periodic array 142 set forth in equation (1) above, with all the other parameters in equation (1) being known. In an exemplary embodiment of OPV 101 fabrication, the desired periodicity p at which the peak transmission wavelength of the periodic array 142 formed in the silver anode layer 140 is closest to the peak absorption wavelength of the P3HT:PCBM organic photoactive layer 122 is computed from equation (1) to be 450 nm.

Next, at operation 640, a desired optical transmission bandwidth of the periodic array 142 is defined based on an optical absorption bandwidth of the organic photoactive layer 122. In an exemplary embodiment of OPV 101 fabrication, the optical absorption bandwidth of the P3HT:PCBM organic photoactive layer 122 is known to correspond to the green region of the visible spectrum, between 400 nm to 650 nm. Accordingly, the desired optical transmission bandwidth of the periodic array 142 is selected to fall within the visible and near-infrared regions of the electromagnetic spectrum, or between 380 nm to 650 nm, which includes the green region of the visible spectrum corresponding to the optical absorption bandwidth of the P3HT:PCBM organic photoactive layer 122.

Following operation 640, a desired diameter d of each of the nanoholes 144 and a desired thickness t of the metal anode electrode layer 140 are defined based on the desired optical transmission bandwidth of the periodic array 142, as shown at operation 650. It is known that the nanohole periodicity p and metal anode type are dependent on the peak optical transmission wavelengths, or the specific wavelengths of light that will resonate and transmit through nanohole arrays. It is further known that the optical transmission bandwidth of the period array 142 is dependent on the nanohole diameter d and metal thickness t. Accordingly, in an exemplary OPV 101 fabrication, based on the desired optical transmission bandwidth of the periodic array 142, which is determined from operation 640 to be between 380 nm to 850 nm, the diameter d of each of the nanoholes 144 and the desired thickness t of the silver anode electrode layer 140 are defined to be 100 nm and about 105 nm, respectively.

Following operation 650, the preliminary steps for pre-defining the geometric parameters of the periodic array 142 and the sub-wavelength nanoholes 144 are completed. The method 500 illustrated in FIG. 5 adapted to fabricate the OPV 101 may follow operation 650 such that the metal anode electrode layer 140 may be subsequently formed on the carrier substrate 150 at operation 510 with the desired layer thickness h determined from operation 650. In an exemplary OPV 101 fabrication, the silver anode electrode layer 140 is therefore formed with the desired thickness of about 105 nm on the carrier substrate 150 based on the thickness determined from operation 650.

Following operation 510, the periodic array 142 may be formed during operation 520 in the metal anode electrode layer 140 with the desired diameter d (determined at operation 650) for each of the nanoholes 144 and with the desired periodicity p (determined at operation 630), which in the exemplary OPV 101 fabrication are determined to be 100 nm and 450 nm for diameter d and periodicity p, respectively.

Following operation 520, the method 500 proceeds to steps 530 and 540 to complete the OPV 101 fabrication as shown in FIG. 5 and discussed above.

Referring to FIG. 7, the preliminary steps for pre-defining the geometric parameters of the periodic array 142 and the sub-wavelength nanoholes 144 to be formed in the metal anode electrode layer 140 prior to the commencement of the method 500 and are particularly adapted to optimally fabricate the OLED 102 are shown. The preliminary configuration steps as shown in FIG. 7 are similar to the corresponding preliminary steps shown in FIG. 6 adapted for the fabrication of the OPV 101.

As noted above, for OLED 102 fabrication, the optical properties of the periodic array 142 is preferably defined to match or correspond with the optical properties of the organic emissive electroluminescent layer 126 in the OLED 102 to thereby allow the specific wavelengths (colors) at which the light 162 is emitted by the organic emissive electroluminescent layer 126 to transmit through the otherwise optically opaque metal anode electrode layer 140. The steps as shown in FIG. 7 may be performed to affect such photonic transmission.

Referring still to FIG. 7, similar to that shown in FIG. 6, the preliminary steps for pre-defining the geometrical parameters of the periodic array 142 and the sub-wavelength nanoholes 144 adapted for OLED 101 fabrication begins at operation 710, at which a peak optical emission wavelength of the organic emissive electroluminescent layer 126 to be formed at least partially on the metal anode electrode layer 140 is determined.

Next, at operation 720, similar to operation 620 adapted for OPV 101 fabrication, a desired peak optical transmission wavelength of the periodic array 142 adapted to be formed in the metal anode electrode layer 140 for OLED 102 fabrication is based on the peak optical emission wavelength of the organic emissive electroluminescent layer 126 determined at operation 710.

Following operation 720, a desired periodicity p of the periodic array 142 is determined at operation 730 based at least in part on the desired peak optical transmission wavelength of the periodic array 142 determined at 720, a dielectric constant of the carrier substrate 150, and a dielectric constant of the metal anode electrode layer 140. The periodicity of the periodic array 142 may be determined based on the first order approximation of the peak optical transmission wavelength λ_{SP}(i,j) of the periodic array 142 set forth in equation (1) above, similar to that as described in operation 630.

Next, at operation 750, a desired optical transmission bandwidth of the periodic array 142 of the OLED 102 is defined based on an optical emission bandwidth of the organic emissive electroluminescent layer 126, after which a desired diameter d of each of the nanoholes 144 and a desired thickness h of the metal anode electrode layer 140 may be defined based on the desired optical transmission bandwidth of the periodic array 142, as shown at operation 760.

Following operation 760, the preliminary steps for pre-defining the geometrical parameters of the periodic array 142 and the sub-wavelength nanoholes 144 for OLED 102 fabrication are completed, and the method 500 illustrated in FIG. 5 adapted to fabricate the OLED 102 may begin thereafter at operation 510 such that the metal anode electrode layer 140 may be formed with the desired thickness h (determined at operation 750) at least partially on the carrier substrate 150. Following operation 510, the periodic array 142 may be formed during operation 520 in the metal anode electrode layer 140 with the desired geometric dimension d (determined at operation 750) for each of the nanoholes 144 and with the desired periodicity p (determined at operation 730). Following operation 520, the method 500 may proceed to steps 530 and 540 to complete the OLED 102 fabrication as shown in FIG. 5 and as similarly described in connection with the OPV 101 fabrication above.

Accordingly, as described, the OOD 100 and the particular exemplary OPV 101 and OLED 102 constructions (the “Devices”), and the method of manufacturing an OOD 100, which may be particular adapted to manufacture an OPV 101 and OLED 102 (the “Methods”), may advantageously be used to improve on conventional ITO-based OODs. The Devices and Methods according to embodiments of the invention may desirably provide at least one or more of the following advantages:

### A. Lower Manufacturing Costs

Certain embodiments of the perforated metal anode electrode layer 146-based Devices and Methods may desirably cost less to manufacture than prior art ITO-based OODs due to the lower metal anode materials (e.g. Au, Ag, and Cu) cost as compared to ITO. Further, as compared to prior art ITO-based OODs which may require additional protective layers in order to protect against the effect of harmful UV wavelengths that may penetrate through the transparent ITO conductor and adversely impact on the organic layers, the perforated metal anode electrode layer 146 may be configured to function as a spectral filter to block or reflectively filter harmful UV without the addition of additional protective layers, thereby lowering the manufacturing costs and simplifying the manufacturing process.

### B. Higher Device Stability:

As compared to the rigid nature of ITO used in prior art OOD applications which may be susceptible to cracking upon bending and the tendency for ITO to degrade or decompose after prolonged use, both of which may result in the penetration of oxygen and moisture into the organic layers, the metal anode materials used in certain embodiments of the Methods and Devices may desirably provide oxygen and moisture resistance and thereby prolong OOD device operational lifetime.

### C. Higher Anode Conductivity

The prior art devices using ITO compromise between conductivity (carrier mobility) and optical transmission. The anode materials selected to form the perforated metal anode layer 146 according to the Devices and Methods embodiments of the invention may be selected from conductive metals such as Ag, Au, and Cu, and may be further configured for enhanced optical transmission, thereby effectively avoiding the comprise which exists in conventional ITO-OODs.

### D. Higher Efficiency

As applied to OPV 101 device fabrication, certain Devices and Methods of the embodiments of the invention have shown an increase in higher power output and/or power conversion efficiency as compared to an ITO-based OPV. In certain embodiments as applied to OLED 102, the optical transmission properties of the period nanohole array 142 of the OLED 102 may be configured such that the intensity of the light 162 emitted by the organic emissive electroluminescent layer 126 and transmitted through the nanoholes 144 are enhanced, thereby resulting in an increased apparent “brightness” in OLED 102 illumination and efficiency as compared to a conventional ITO-OLED.

### Test Results

In one embodiment of the invention, to determine whether the 450 nm nanohole periodicity theoretically determined at operation 620 shown in the preliminary configuration steps of FIG. 6 for OPV 101 fabrication would in fact translate to an enhanced photonic absorption at the P3HT:PCBM organic photoactive layer 122, a number of perforated silver anode layer (hereinafter “Ag_{SPP}”) were fabricated with periodicities varying from 400 nm to 600 nm, and the transmission intensities of the respective Ag_{SPP} were measured for empirical comparison. In one such exemplary test configuration, the photonic properties of the nanohole arrays were characterized in dark field illumination with linearly polarized light on a Zeiss® Axio Imager™ M1m optical microscope. Scattered light from the nanoholes 144 were collected using a 100× objective and analyzed using a PI/Acton® MicroSpec™-2360 spectrometer with a PIXIS™ 400BR CCD camera system.

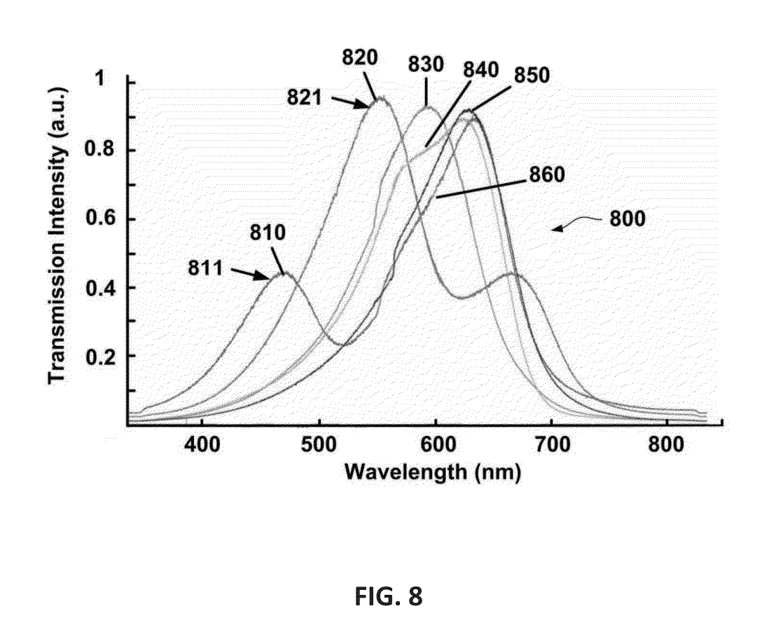

As discussed below with reference to FIG. 8 and Table 1, results according to one empirical embodiment of the invention show that in fact a periodic array with 450 nm periodicity, as opposed to the theoretically determined periodicity of 400 nm, may yield a preferable combination of transmission intensity peaks and bandwidth according to one embodiment of the invention.

Referring to FIG. 8, a plot 800 showing transmission curves 810, 820, 830, 840, 850, and 860 (i.e. intensity versus wavelength) of silver metal anode layers 140 perforated with respective periodic nanohole arrays of 400 nm, 450 nm, 500 nm, 550 nm, and 600 nm in periodicity are shown, according to one embodiment. The perforated silver metal anode layers 146 with periodicities varying from 400 nm to 600 nm were fabricated on a glass carrier substrate 150 according to the exemplary method 500 illustrated in FIG. 5 adapted for the exemplary OPV 101 fabrication. That is, the perforated silver metal anode layers 146 of varying periodicities each have nanohole geometric dimensions (in this case diameters) d of about 100 nm, and nanohole heights h of about 105 nm.

For comparison with Ag_{SPP} fabricated on glass carrier substrates 150 shown in FIG. 8, Ag_{SPP} with the same varying periodicities from 400 nm to 600 nm are also fabricated on PET carrier substrates 150. The measured (first order) peak optical transmission wavelengths λ_{SPP} of the perforated silver metal anode layers 146 of the OPVs 101 fabricated on glass and PET carrier substrates 150 are respectively shown in columns 4 and 5 in Table 1 below for different nanohole periodicities. The estimated (first order) peak optical transmission wavelengths λ_{SPP} computed according to equation (1) are also shown in columns 2 and 3, according to one embodiment.

TABLE 1
First order peak transmission wavelengths
λ_{SPP} for nanohole arrays on Ag films.

| | Estimate (0, 1) λ_{SPP} (nm) | | Measured (0, 1) λ_{SPP} (nm) | |
|---|---|---|---|---|
| Periodicity (nm) | Glass | PET | Glass | PET |
| 400 | 480 | 539 | 486 | 545 |
| 450 | 540 | 606 | 567 | 633 |
| 500 | 600 | 674 | 606 | 679 |
| 550 | 660 | 741 | 633 | 714 |
| 600 | 720 | 809 | 643 | 731 |

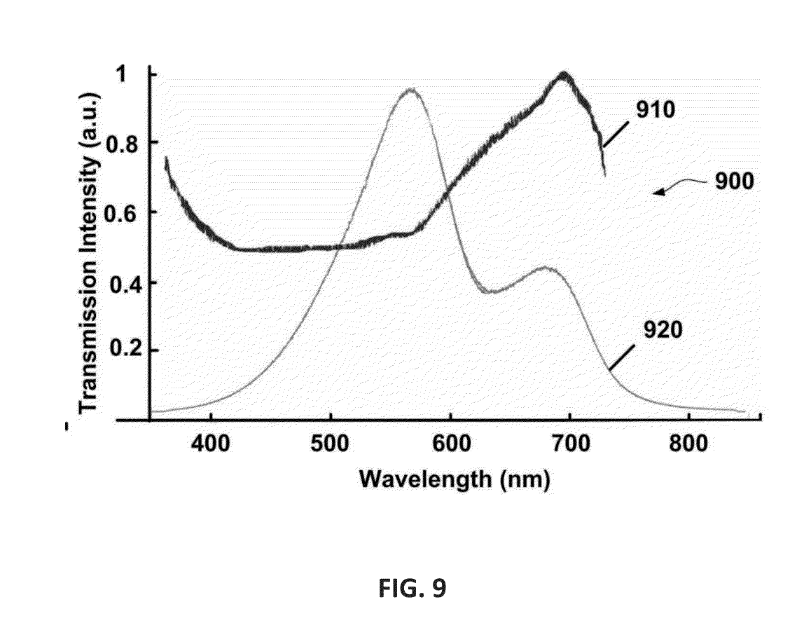

As shown in FIG. 8, although an Ag_{SPP} with an exemplary periodic array 142 of 400 nm periodicity (curve 810) results in a (first order) peak optical transmission wavelength λ_{SPP} of 486 nm (at the location on the curve 810 pointed to by the arrow of reference numeral 811), which closely matches to that of the peak optical absorption wavelength of the exemplary P3HT:PCBM organic photoactive layer 122 of about 500 nm (not shown), the transmission intensity 811 at the peak optical transmission wavelength λ_{SPP} of 486 nm is in fact relatively low, at approximately 0.4 arbitrary units (“a.u.”), according to one embodiment. From observing FIG. 8 and Table 1, it is in fact the 450 nm periodicity (curve 820) nanohole arrays that yields the best combination of measured first order transmission intensity peak 821 of about 0.9 a.u. and measured bandwidth between 380 nm to 850 nm, with peak optical transmission wavelengths λ_{SPP} at 567 nm and 633 nm as shown in Table 1 for glass and PET respectively. As noted, the exemplary P3HT:PCBM organic photoactive layer 122 absorbs photons in the green region of the visible spectrum corresponding to a bandwidth between 495 nm to 570 nm, and has a peak optical absorption wavelength of about 480 nm. Fabricating Ag_{SPP} with an exemplary periodic array 142 of 450 nm periodicity therefore ensures that the nanoholes 144 has a wide enough transmission bandwidth (between 380 nm to 850 nm) to allow photons in the green region of the visible spectrum to transmit therethrough, and undergo an enhanced optical transmission at selected wavelengths (λ_{SPP} of 567 nm for glass or λ_{SPP} of 633 nm for PET), which can then be effectively absorbed by the exemplary P3HT:PCBM organic photoactive layer 122 for photovoltaic conversion. The improvements in transmission of a Ag_{SPP} with an exemplary periodicity of 450 nm relative to a conventional ITO can further be observed in FIG. 9.

Referring now to FIG. 9, a plot 900 of a transmission curve 910 of an Ag_{SPP} layer with a periodicity of 450 nm and a transmission curve 920 of a conventional ITO on glass are shown, according to an embodiment of the present invention. As shown in FIG. 9, between the exemplary wavelengths of 500 nm and 600 nm, an improvement in transmission corresponding to an increase in transmission intensity from about 0.5 a.u. in curve 910 for the conventional ITO-OPV to about 1 a.u. in curve 920 for the Ag_{SPP} is observed. In one embodiment, this improvement in transmission translates to a three-fold increase in Power Conversion Efficiency (“PCE”) for Ag_{SPP}-OPVs as compared to conventional ITO-OPVs, as discussed below with reference to FIGS. 10 and 11.

In another exemplary embodiment, current density-voltage (J-V) characteristics for the ITO-OPV and perforated silver anode layers based OPVs devices (hereinafter “Ag_{SPP}-OPVs”) on glass respectively, were determined. In such an embodiment, ITO (100 nm thick ITO, 20 Ω/cm²) may be made in substantially the same process as making the exemplary OPV 101 as discussed with reference to FIGS. 6 and 7. In one such embodiment, two exemplary reference ITO-OPV cells on an exemplary glass substrate were fabricated for comparison with three exemplary Ag_{SPP}-OPV cells fabricated on an exemplary glass substrate. To measure the relevant current density-voltage characteristics, the ITO-OPV and Ag_{SPP}-OPV cells were illuminated with a suitable solar simulator at room temperature in air, and their respective two-terminal current density-voltage (J-V) measurements were collected. Comparison of the resulting current density-voltage characteristics of the exemplary ITO-OPV cell results to the exemplary Ag_{SPP}-OPV cells, the Ag_{SPP}-OPV cells show an exemplary relative efficiency increase of 3.1 times relative to that of the exemplary ITO-OPV cells. Accordingly, these test results indicate that the exemplary Ag_{SPP}-OPVs according to one embodiment of the present invention may be particularly applicable in powering electronic devices that typically demand high power consumption and increased efficiency which may be unmet by conventional ITO-OPVs.

In particular exemplary embodiments of the present invention, periodic nanofeature arrays embodying any suitable desired periodicity or spacing may be formed on OPV cells according to the present invention and arranged in any suitable or desired formation or pattern. In one such embodiment, periodic nanohole arrays may comprise one or more of: triangular, square, hexagonal or any other desired polygonal grid patterns, circular or concentric circular patterns, or circular slot or concentric circular slot patterns, for example.

The exemplary embodiments herein described are not intended to be exhaustive or to limit the scope of the invention to the precise forms disclosed. They are chosen and described to explain the principles of the invention and its application and practical use to allow others skilled in the art to comprehend its teachings.

As will be apparent to those skilled in the art in light of the foregoing disclosure, many alterations and modifications are possible in the practice of this invention without departing from the spirit or scope thereof. Accordingly, the scope of the invention is to be construed in accordance with the substance defined by the following claims.

What is claimed is:

1. An organic optoelectronic device, comprising:
a carrier substrate;
an anode electrode layer disposed at least partially on the carrier substrate, the anode electrode layer having a periodic array of sub-wavelength nanostructures;
an organic electronic active region disposed at least partially on the anode electrode layer, the organic electronic active region comprising one or more organic layers; and
a cathode electrode layer disposed at least partially on the organic electronic active region.

2. The organic optoelectronic device according to claim 1, wherein the nanostructures have a periodicity between about 250 nanometers (nm) and about 1400 nanometers (nm).

3. The organic optoelectronic device according to claim 1, wherein the nanostructures comprise nanoholes.

4. The organic optoelectronic device according to claim 3, wherein the nanoholes each have a diameter of about 100 nanometers (nm).

5. The organic optoelectronic device according to claim 1, wherein the nanostructures each have a depth corresponding to a thickness of the anode electrode layer.

6. The organic optoelectronic device according to claim 1, wherein the anode layer comprises at least one of a metallic material, semiconductor material, and conductive polymer material, wherein a work function of the anode layer is compatible with the organic active layer.

7. The organic optoelectronic device according to claim 1 wherein the organic optoelectronic device comprises one of:
an organic photovoltaic device, wherein said organic electronic active region comprises an organic photoactive layer disposed at least partially on the anode electrode layer; and
an organic light emitting diode device, wherein said organic electronic active region comprises an organic emissive electroluminescent layer disposed at least partially on the anode electrode layer.

8. The organic optoelectronic device according to claim 7, wherein the periodic array of sub-wavelength nanostructures has an optical transmission spectrum corresponding to one of:
an optical absorption spectrum of the organic photoactive layer of the organic photovoltaic device; and
an optical emission spectrum of the organic emissive electroluminescent layer of the organic light emitting diode device.

9. The organic optoelectronic device according to claim 7, wherein the organic emissive electroluminescent layer of the organic light emitting diode device is configured to emit light, the periodic array of sub-wavelength nanostructures being geometrically, optically and spatially configured to permit the light emitted by the organic emissive electroluminescent layer to pass therethrough.

10. The organic optoelectronic device according to claim 1, wherein the periodic array of sub-wavelength nanostructures has an optical transmission bandwidth which may be configured by selection of at least one of a geometric dimension of the nanostructures and a thickness of the anode electrode layer.

11. The organic optoelectronic device according to claim 8, wherein the optical absorption spectrum of the organic photoactive layer of the organic photovoltaic device may be configured by selection of at least one of a periodicity of the periodic array of sub-wavelength nanostructures and a material composing the anode electrode layer.

12. The organic optoelectronic device according to claim 7, wherein the organic photoactive layer comprises at least one of:
poly(3-hexylthiophene):[6,6]-phenyl-C₆₁-butyric acid methyl ester (P3HT:PCBM); and
poly[[9-(1-octylnonyl)-9H-carbazole-2,7-diyl]-2,5-thiophenediyl-2,1,3-benzothiadiazole-4,7-diyl-2,5-thiophenediyl]:[6,6]-phenyl-C₆₁-butyric acid methyl ester (PCDTBT:PC70BM).

13. The organic optoelectronic device according to claim 1, wherein the carrier substrate comprises a flexible and/or a rigid material such as PolyEthylene Terephthalate (PET) and/or glass).

14. The organic optoelectronic device according to claim according to claim 7, wherein the organic photovoltaic device further comprises an organic hole transport layer disposed at least partially between the anode electrode layer and the organic photoactive layer.

15. The organic optoelectronic device according to claim according to claim 14, wherein the organic hole transport layer comprises:
poly(3,4-ethylenedioxythiophene):poly(styrenesulfonate) (PEDOT:PSS).

16. The organic optoelectronic device according to claim 1, wherein said nanostructures comprise one or more of: at least one nanohole array, a plurality of annular openings concentrically disposed about a central nanohole, a plurality of nanoholes arranged in a plurality of rings concentrically disposed about a central nanohole, and an annular opening.

17. The organic optoelectronic device according to claim 16, wherein said plurality of annular openings comprise two annular openings concentrically disposed about said central nanohole.

18. The organic optoelectronic device according to claim 16, wherein said nanostructures are arranged in at least one of a hexagonal, square, rhombic, rectangular, or parallelogrammatic lattice.

19. A method of manufacturing an organic optoelectronic device, comprising
forming an anode electrode layer at least partially on a carrier substrate;
forming a periodic array of sub-wavelength nanostructures in the anode electrode layer defined as a perforated metal anode electrode layer;
forming an organic electronic active region at least partially on the perforated anode electrode layer, the organic electronic active region comprising one or more organic layers; and
forming a cathode electrode layer at least partially on the organic electronic active region.

20. A method of manufacturing an organic photovoltaic device, comprising:
determining a peak optical absorption wavelength of an organic photoactive layer to be formed at least partially on an anode electrode layer;
defining a desired peak optical transmission wavelength of a periodic array of sub-wavelength nanostructures adapted to be formed in the anode electrode layer based on said determined peak optical absorption wavelength of said organic photoactive layer;
determining a desired periodicity of said periodic array of sub-wavelength nanostructures based at least in part on said desired peak optical transmission wavelength of said periodic array of sub-wavelength nanostructures, a dielectric constant of said carrier substrate, and a dielectric constant of said anode electrode layer;
defining a desired optical transmission bandwidth of said periodic array of sub-wavelength nanostructures based on an optical absorption bandwidth of said organic photoactive layer;
defining a desired geometric dimension of each of said nanostructures and a desired thickness of said anode electrode layer based on said desired optical transmission bandwidth of said periodic array of sub-wavelength nanostructures;
forming said anode electrode layer with said desired thickness at least partially on a carrier substrate;
forming said periodic array of sub-wavelength nanostructures in said anode electrode layer with said desired geometric dimension for each of said nanostructures and with said desired periodicity;
forming an organic photoactive layer at least partially on said anode electrode layer; and
forming a cathode electrode layer at least partially on said organic photoactive layer.

21. A method of manufacturing an organic light emitting diode device, comprising:
determining a peak optical emission wavelength of an organic emissive electroluminescent layer to be formed at least partially on a anode electrode layer;
defining a desired peak optical transmission wavelength of a periodic array of sub-wavelength nanostructures adapted to be formed in the anode electrode layer based on said determined peak optical emission wavelength of said organic emissive electroluminescent layer;
determining a desired periodicity of said periodic array of sub-wavelength nanostructures based at least in part on said desired peak optical transmission wavelength of said periodic array of sub-wavelength nanostructures, a dielectric constant of said organic emissive electroluminescent layer, and a dielectric constant of said anode electrode layer;
defining a desired optical transmission bandwidth of said periodic array of sub-wavelength nanostructures based on an optical transmission bandwidth of said organic emissive electroluminescent layer;
defining a desired geometric dimension of each of said nanostructures and a desired thickness of said anode electrode layer based on said desired optical transmission bandwidth of said periodic array of sub-wavelength nanostructures;
forming said anode electrode layer with said desired thickness at least partially on a carrier substrate;
forming said periodic array of sub-wavelength nanostructures in said anode electrode layer with said desired geometric dimension for each of said nanostructures and with said desired periodicity;
forming an emissive electroluminescent layer at least partially on said anode electrode layer; and
forming a cathode electrode layer at least partially on said organic emissive electroluminescent layer.

22. An organic optoelectronic device, comprising:
a carrier substrate;
a cathode electrode layer disposed at least partially on the carrier substrate, the cathode electrode layer having a periodic array of sub-wavelength nanostructures;
an organic electronic active region disposed at least partially on the cathode electrode layer, the organic electronic active region comprising one or more organic layers; and
an anode electrode layer disposed at least partially on the organic electronic active layer.

23. The organic optoelectronic device according to claim 22 wherein the organic optoelectronic device comprises one of:
an organic photovoltaic device, wherein said organic electronic active region comprises an organic photoactive layer disposed at least partially on the cathode electrode layer; and
an organic light emitting diode device, wherein said organic electronic active region comprises an organic emissive electroluminescent layer disposed at least partially on the cathode electrode layer.

24. The organic photovoltaic device according to claim 23, wherein the organic photovoltaic device further comprises an organic hole transport layer disposed at least partially between the anode electrode layer and the organic photoactive layer.

25. The organic photovoltaic device according to claim according to claim 24, wherein the organic hole transport layer comprises:
poly(3,4-ethylenedioxythiophene):poly(styrenesulfonate) (PEDOT:PSS).

26. The organic optoelectronic device according to claim 22, wherein said nanostructures comprise one or more of: at least one nanohole array, a plurality of annular openings concentrically disposed about a central nanohole, a plurality of nanoholes arranged in a plurality of rings concentrically disposed about a central nanohole, and an annular opening.
